(19) United States
(12) Patent Application Publication
(10) Pub. No.: US 2026/0219580 A1
(43) Pub. Date: Jul. 30, 2026

(54) FACET MIRROR FOR AN ILLUMINATION OPTICAL UNIT FOR PROJECTION LITHOGRAPHY SUITABLE FOR USE AS FIRST FACET MIRROR

(71) Applicant: Carl Zeiss SMT GmbH, Oberkochen (DE)

(72) Inventor: Martin ENDRES, Königsbronn (DE)

(21) Appl. No.: 19/629,992

(22) Filed: Mar. 26, 2026

Related U.S. Application Data
(63) Continuation of application No. PCT/EP2024/075910, filed on Sep. 17, 2024.

(30) Foreign Application Priority Data
Oct. 4, 2023 (DE) 10 2023 209 709.5
Oct. 4, 2023 (DE) 10 2023 209 710.9

(51) Int. Cl. G03F 7/00

(52) U.S. Cl. CPC G03F 7/70075; G03F 7/70116

(57) ABSTRACT

A facet mirror for a projection lithography illumination optical unit is suitable for use as first facet mirror such that individual mirror groups of the facet mirror, as first facets, are imaged at least into partial fields of an object field of the illumination optical unit with the aid of a transfer optical unit. The facet mirror has an array arrangement of individual mirror units, with each individual mirror unit being a sub-array of individual mirrors. The facet mirror has at least two pre-tilt types of the individual mirror units. A first pre-tilt type has individual mirror units which, in a neutral position, have a first pre-tilt angle relative to a base tilt angle specified by a carrier geometry of the facet mirror. A second pre-tilt type has individual mirror units with a second pre-tilt angle different from the first pre-tilt angle.

### CROSS-REFERENCE TO RELATED APPLICATIONS

The present application is a continuation of, and claims benefit under 35 USC 120 to, international application No. PCT/EP2024/075910, filed Sep. 17, 2024, which claims benefit under 35 USC 119 of German Application No. DE 10 2023 209 710.9 and DE 10 2023 209 709.5, filed Oct. 4, 2023. The entire disclosure of each of these applications is incorporated by reference herein.

### FIELD

The disclosure relates to a facet mirror for an illumination optical unit for projection lithography suitable for use as first facet mirror. Furthermore, the disclosure relates to an illumination optical unit having such a facet mirror, to an illumination system having such an illumination optical unit, to an optical system having such an illumination optical unit, to a projection exposure apparatus having such an optical system, to a method for producing a microstructured or nanostructured component with such a projection exposure apparatus and to a microstructured or nanostructured component produced with such a method.

### BACKGROUND

A facet mirror is known from DE 10 2015 208 512 A1.

### SUMMARY

The present disclosure seeks to provide a facet mirror of the type such that allows for relaxation of the properties for a tilt actuator system for tilting individual mirrors of the facet mirror.

In a first aspect, the disclosure provides a facet mirror for an illumination optical unit for projection lithography, suitable for use as first facet mirror such that individual mirror groups of the facet mirror, as first facets, are imaged at least into partial fields of an object field of the illumination optical unit with the aid of a transfer optical unit, an object being arrangeable in the object field and being displaced in an object displacement direction through the object field during a projection exposure. The facet mirror has an array arrangement of individual mirror units, with each of the individual mirror units being embodied as a sub-array of individual mirrors. There are at least two pre-tilt types of the individual mirror units. A first pre-tilt type comprises individual mirror units which, in a neutral position, have a first pre-tilt angle relative to a base tilt angle specified by a carrier geometry of the facet mirror. A second pre-tilt type comprises individual mirror units which, in the neutral position, have a second pre-tilt angle relative to the base tilt angle. The pre-tilt angles of the different pre-tilt types differ from one another. The pre-tilt angles are in the range between 10 mrad and 500 mrad.

In a second aspect, the disclosure provides an illumination optical unit having a first facet mirror, a second facet mirror and a transfer optical unit. The illumination optical unit is embodied such that individual mirror groups of the first facet mirror, as first facets, are imaged at least into partial fields of an object field of the illumination optical unit with the aid of the transfer optical unit, an object being arrangeable in the object field and being displaced in an object displacement direction through the object field during a projection exposure. The first facet mirror comprises: a regular array arrangement of individual mirror units, with each of the individual mirror units being embodied as a sub-array of individual mirrors; and at least two coating types of the individual mirror units. A first coating type comprises individual mirror units which, in a neutral position, are optimized for a first angle of incidence of illumination light on the individual mirror units of this coating type. A second coating type comprises individual mirror units which, in the neutral position, are optimized for a second angle of incidence of the illumination light on the individual mirror units of this coating type. The angles of incidence of the different coating types differ from one another. The second facet mirror is for reflecting guidance of the illumination light reflected by the first facet mirror to the object field. The second facet mirror comprises second facets which image groups of individual mirrors of the first facet mirror, as first facets, at least into partial fields of the object field via illumination light component beams. At least two target surface regions are present on the second facet mirror along a field height arrangement coordinate of the second facet mirror of the illumination optical unit. The field height arrangement coordinate corresponds to a field height coordinate of the first facet mirror which is imaged by the illumination optical unit into a field height coordinate perpendicular to the object displacement direction coordinate of the object field, with each of the target surface regions being provided for guiding illumination light via a pre-tilt type in each case and/or via a coating type of the first facet mirror in each case.

In a third aspect, the disclosure provides an illumination optical unit having a first facet mirror, a second facet mirror and a transfer optical unit. The first facet mirror has first facets for reflecting guidance of component beams of illumination light. The second facet mirror is for reflecting guidance of the illumination light reflected by the first facet mirror to the object field. The illumination optical unit is embodied such that the first facets of the first facet mirror are imaged at least into partial fields of an object field of the illumination optical unit with the aid of the transfer optical unit, which includes second facets of the second facet mirror, an object being arrangeable in the object field and being displaced in an object displacement direction through the object field during a projection exposure. The second facet mirror comprises at least two pre-tilt types of the second facets, wherein a first pre-tilt type comprises second facets which, in a neutral position, have a first pre-tilt angle relative to a base tilt angle specified by a carrier geometry of the facet mirror, wherein a second pre-tilt type comprises second facets which, in the neutral position, have a second pre-tilt angle relative to the base tilt angle, and wherein the pre-tilt angles of the different pre-tilt types differ from one another. And/or the second facet mirror comprises at least two coating types of the second facets, wherein a first coating type comprises second facets and/or individual mirror units which are optimized for a first interval of angles of incidence of illumination light on the second facets and/or the individual mirror units of this coating type, wherein a second coating type comprises second facets and/or individual mirror units which are optimized for a second interval of angles of incidence of the illumination light on the second facets and/or the individual mirror units of this coating type, and wherein the angles of incidence intervals of the different coating types differ from one another. The second facets of the second facet mirror image first facets at least into partial fields of the object field via illumination light component beams. At least two initial surface regions are present on the first facet mirror along a field height coordinate of the first facet mirror of the illumination optical unit, the field height coordinate being imaged using the illumination optical unit into a field height coordinate perpendicular to the object displacement coordinate of the object field, with each of the initial surface regions being provided for guiding illumination light component beams via a pre-tilt type in each case and/or via a coating type of the second facet mirror in each case.

According to the disclosure, it was identified that a provision of at least two pre-tilt types of facets of the facet mirror relax structural properties placed on a tilt actuator system of the facet mirror for example. For example, a desired tilt range can be reduced in that case. The facet mirror can have at least two pre-tilt types which differ in terms of the pre-tilt angle relative to the base tilt angle. The pre-tilt angles can be in the range between 10 mrad and 500 mrad, for example between 20 mrad and 200 mrad, for example between 30 mrad and 80 mrad.

The different pre-tilt types are also referred to as switching classes.

The number of individual mirror units belonging to a respective one of the pre-tilt types can be so large that they do not differ by more than 10%. In alternative to that, it is possible to assign a first number of associated individual mirror units to specific pre-tilt types, and for example a smaller number of individual mirror units to further pre-tilt types.

Should the numbers of the individual mirror units belonging to a respective one of the pre-tilt types not differ substantially from one another, they might differ by no more than 10%, by no more than 5%, by no more than 2%, or by no more than 1%. The number of individual mirror units belonging to a respective one of the pre-tilt types may also be the same with regards to a few of the different pre-tilt types or with regards to all of the different pre-tilt types.

Optionally, the facet mirror can comprise exactly two pre-tilt types or else comprise more than two pre-tilt types, for example three, four, five or even more pre-tilt types. The facet mirror regularly has fewer than 20 pre-tilt types.

Due to the pre-tilt of the individual mirror groups, the relaxed properties placed on the tilt actuator system for tilting the individual mirrors of the individual mirror units can allow for the use of tilt actuators with a smaller overall tilt range. This can render types of tilt actuators accessible which can be produced especially within the scope of mass production technologies.

It is possible to achieve both a reduction in the maximum angle of incidence and a reduction in the maximum angle of incidence travel on the individual mirrors. This can optimize a reflection yield of the facet mirror.

The individual mirror units can be present in the form of a regular array arrangement with for example K lines and L columns. The lines or the columns can also be arranged in a manner displaced from one another.

In embodiments of the second aspect, there is an array arrangement of individual mirror units of the second facet mirror, with each of the second facets being embodied as a sub-array of individual mirrors of the respective individual mirror unit and all individual mirrors of an individual mirror unit belonging to exactly one pre-tilt type. Such a design of the facet mirror can allow a high packing density of individual mirror groups of the first facet mirror with the same pre-tilt type, which are imaged via a further facet mirror of the illumination optical unit at least into partial fields of the object field. The larger the contiguous mirror surface pre-tilt type sections of the facet mirror, the lower the probability that corresponding individual mirror groups are curtailed at edges of the mirror surface pre-tilt type sections; this curtailment would reduce an efficiency of an illumination light throughput of an illumination optical unit having such a facet mirror. When subdividing the facet mirror into mirror surface pre-tilt type sections comprising respective groups of the individual mirror units, it is possible in each case to find a compromise between the targets of “high illumination light throughput of the illumination optical unit having the facet mirror” and “good light mixing due to the use of individual mirror groups that are spaced apart on the facet mirror”. In the process, switching angles of the individual mirrors of the first facet mirror are able to be reduced when switching between different illumination angle distributions to be provided by way of the illumination optical unit, and a high illumination light throughput is able to be obtained at the same time by way of a high packing density of an occupancy of the first facet mirror with individual mirror groups. Such a design can facilitate a structural design since all individual mirror units within the respective contiguous mirror surface pre-tilt type section are pre-tilted in the same way. The individual mirror units of at least one of the pre-tilt types can in turn be arranged in groups of individual mirror units in at least two mirror surface pre-tilt type sections of the facet mirror which can be disjoint from one another for example. This allows good light mixing during the operation of the illumination optical unit.

In embodiments, there is a twofold or multiply rotationally symmetric arrangement of the mirror surface pre-tilt type sections, in which different ones of the pre-tilt types are arranged. Such an arrangement can also have desirable light mixing properties. The arrangement of the mirror surface pre-tilt type sections, in which different pre-tilt types are arranged, on the facet mirror can have a twofold or else a multiple rotational symmetry. A mirror symmetric arrangement or else a point symmetric arrangement is also possible.

In embodiments, an extent of the mirror surface pre-tilt type sections can help ensure that an entire object field width can in fact be imaged with the aid of exactly one pre-tilt type section. This facilitates an assignment of individual mirror groups of the facet mirror to object field sections.

In embodiments, a line-by-line arrangement of the mirror surface pre-tilt type sections can orient itself according to a line-by-line arrangement of the individual mirror units; this is desirable for example when using the facet mirror in an illumination optical unit for illuminating rectangular object fields. Moreover, this line-by-line arrangement can facilitate the structural embodiment of the facet mirror. Such a line-by-line arrangement can orient itself according to a line-by-line arrangement along a field height coordinate of the facet mirror; especially for arcuate object fields, this can offer desirable assignment properties of the individual mirrors of the respective pre-tilt type to individual mirror groups, which in turn are imaged in partial fields of the object field.

The line-by-line arrangement of the mirror surface pre-tilt type sections on the facet mirror can be such that a total of at least three mirror surface pre-tilt type sections alternate line-by-line on the facet mirror; in their neutral position, the mirror surface pre-tilt type sections apply illumination light to a central section of a further facet mirror of the illumination optical unit, to a first peripheral section of this further facet mirror and to an opposite second peripheral section of this facet mirror when the facet mirror is used in the illumination optical unit.

The features of an illumination optical unit can correspond to those which were already explained above with reference to the facet mirror, which represents the first facet mirror in this illumination optical unit. The facet mirror can allow an optimized adaptation to expected angles of incidence on the individual mirrors of the individual mirror groups of the respective coating types. The consequence of this can be an improved light throughput overall when reflecting the illumination light at the second facet mirror. The different coating types are also referred to as layer classes.

Such a facet mirror with a plurality of coating types can also comprise a plurality of pre-tilt types at the same time, in accordance with the embodiment of the facet mirror having a plurality of pre-tilt types which was already explained above.

Angles of incidence of the various coating types can differ by 1° to 5°, for example by 2° or by 3°.

The facet mirror can comprise exactly two coating types or else more than two coating types, for example three, four, five or even more coating types. The facet mirror typically has fewer than 20 coating types.

The arrangement of the pre-tilt types or coating types in a manner adapted to the target surface regions of the second facet mirror of the illumination optical unit can take account of the fact that the second facet mirror has a greater extent along the field height arrangement coordinate than along a coordinate perpendicular thereto. The subdivision thus reduces a bandwidth of the expected angles of incidence on the individual mirrors of the respective coating type of the first facet mirror.

In embodiments, a facet mirror with contiguous mirror surface coating type sections can allow a high packing density of individual mirror groups on the facet mirror. The explanations given above with regards to the packing density in the context of the contiguous mirror surface pre-tilt type sections according to embodiments apply here as a matter of principle. Moreover, such an embodiment can facilitate a production of the facet mirror.

The above-described facet mirror embodiments can also be combined with one another, and so the facet mirror can simultaneously have a plurality of pre-tilt types and also a plurality of coating types. Individual mirror units of such a facet mirror which differ in terms of the pre-tilt type may also differ in terms of the coating type. Other assignments are also possible, and so individual mirror groups of the same pre-tilt type might be assigned to different coating types. Individual mirror groups of the same coating type can also be assigned to different pre-tilt types.

In embodiments, an arrangement of the target surface regions can take account of a folding geometry of a guidance of the illumination light through the illumination optical unit and otherwise can have corresponding desirable properties as already explained above.

In embodiments, overlapping target surface regions can increase an assignment flexibility between the mirrors or facets of the two facet mirrors, and this increases degrees of freedom in the case of desired light mixing. Such overlapping target surface regions can be desirable, for example if the illumination optical unit is used to illuminate an arcuate or ring-shaped object field.

A subdivision of the target surface regions on the second facet mirror can be such that two target surface regions whose overlap is small in comparison with the area of the target surface regions, or which do not have any overlap at all, belong to mirror surface pre-tilt type sections of the first facet mirror which, on the first facet mirror, are not present directly adjacently to one another or are only present directly adjacently to one another with a low probability. It is desirable, for example, if the associated mirror surface pre-tilt type sections on the first mirror facet are present on the first facet mirror in a manner separated from one another by a further section which belongs to a further mirror surface pre-tilt type assigned in turn to a target surface region of the second facet mirror which has a relatively large overlap with the two target surface regions mentioned first. This facilitates an occupancy of the first facet mirror with individual mirror groups which are imaged by way of the second facet mirror at least into partial fields of the object field which can be embodied with tight packing and, at the same time, a good reflection efficiency such that a correspondingly high illumination light throughput of the illumination optical unit arises.

The target surface regions can have a rectangular, elliptical or else circular boundary. A polygonal boundary of the target surface regions is also possible.

According to the disclosure, it was moreover identified that a provision of at least two pre-tilt types of facets of the second facet mirror in accordance with a first variant of an illumination optical unit according to third aspect can relax structural properties placed for example on a tilt actuator system of the facet mirror. For example, a desired tilt range can be reduced in that case. The pre-tilt type is also referred to as switching class.

Tilt angle ranges of the second facets can differ, provided a tilt about two different tilt axes or axes of rotation is envisaged. A ratio between these tilt angle ranges can be in the range between 1.1 and 10, and for example in the range between 2 and 5. Different pre-tilt types can have different tilt angle ranges and also different tilt angle range ratios about the tilt axes or axes of rotation, of which optionally multiple are made available.

The second facet mirror has at least two pre-tilt types which differ in terms of the pre-tilt angle relative to the base tilt angle. The pre-tilt angles can be in the range between 10 mrad and 500 mrad, for example between 20 mrad and 200 mrad, for example between 30 mrad and 80 mrad.

Due to the pre-tilt of the individual mirror groups, the relaxed properties placed on the tilt actuator system for tilting the individual mirrors of the individual mirror units allows for the use of tilt actuators with a smaller overall tilt range. This renders types of tilt actuators accessible which can be produced especially within the scope of mass production technologies.

It is possible to realize both a reduction in the maximum angle of incidence and a reduction in the maximum angle of incidence travel on the second facets. This can optimize a reflection yield of the facet mirror.

The arrangement of the mirror surface coating types in a manner adapted to the initial surface regions on the first facet mirror can take account of the fact that, as a result of an extent of the first facet mirror along the field height arrangement coordinate, angle of incidence intervals that are too large would arise for a respective coating type without an appropriate subdivision into initial surface regions. The subdivision thus reduces a bandwidth of the expected angles of incidence on the individual mirrors of the respective coating type of the second facet mirror.

A second facet mirror according to the further variant of the illumination optical unit according to the third aspect with a plurality of coating types of the second facets can allow an optimized adaptation to expected angle of incidence intervals on the individual mirrors of the individual mirror groups of the respective coating types. The different coating types can be adapted to pre-tilt angles of the pre-tilt types, and this leads to a reduction in absolute interval size of the angle of incidence intervals to which the coating types are adapted. The consequence of this is an improved light throughput overall when reflecting the illumination light at the second facet mirror. The different coating types are also referred to as layer classes.

The different pre-tilt types are also referred to as switching classes.

Such a facet mirror with a plurality of coating types can also comprise a plurality of pre-tilt types at the same time, in accordance with the embodiment of the facet mirror having a plurality of pre-tilt types which was already explained above.

The facet mirror embodiments described above can also be combined with one another.

The facet mirror can comprise exactly two coating types or else more than two coating types, for example three, four, five or even more coating types. The facet mirror regularly has fewer than 20 coating types.

In the configuration of the second facet mirror according to embodiments, with individual mirror units which in turn are embodied as a sub-array of individual mirrors, each of the individual mirror units can represent exactly one second facet. Alternatively, each of the individual mirror units can also form a plurality of second facets. For example, if one of the individual mirror units is embodied as a sub-array of 24×24 individual mirrors and each of the second facets occupies a sub-array thereof of 6×6 individual mirrors, then it is possible to specify 16 (4×4) second facets per individual mirror unit. If 8×8 individual mirrors should be used per second facet in such a case, then nine (3×3) second facets can be formed per individual mirror unit with 24×24 individual mirrors. For example, each of the individual mirror units can form 1 to 100 second facets which in turn can have exactly one individual mirror or which in turn are embodied as an individual mirror sub-array.

The facet mirror can have two pre-tilt types or else more than two pre-tilt types, for example three, four, five or even more pre-tilt types, for example eight, nine, ten or even more pre-tilt types.

The pre-tilt types can regularly alternate in chequerboard-like or regular grid-like fashion and be arranged on the facet mirror. Relative to a field height arrangement coordinate of the facet mirror, which corresponds to the field height coordinate imaged using the illumination optical unit into a field height coordinate perpendicular to an object displacement direction coordinate of the object field, such a chequerboard-like or regular grid-like arrangement can be arranged at an angle of between 10° and 80°, for example at an angle of between 30° and 60°, for example at an angle of 45° or else 37°.

An assignment of the individual mirror units to pre-tilt types according to embodiments can allow good mixing of the guidance of illumination light component beams by way of an illumination optical unit which includes the facet mirror. The condition that adjacent individual mirror units belong to different pre-tilt types need not apply to arbitrary pairs of adjacent individual mirror units; instead, it is sufficient for the facet mirror with an appropriate array arrangement of individual mirror units to have mutually adjacent regions with in each case a plurality of individual mirror units of the same pre-tilt type which are adjacent to one another, wherein the pre-tilt types of the various regions differ from one another.

A configuration of the second facets as monolithic facets according to embodiments has proven its worth in practice. In this case, the second facets are not in turn subdivided into a plurality of individual mirrors.

The features of a configuration in which adjacent second facets belong to different pre-tilt types, according to embodiments, in general correspond to those that were already explained above with reference to the plurality of pre-tilt types. Even if the different pre-tilt types are used in the case of monolithic second facets, these pre-tilt types can regularly alternate in chequerboard-like or regular grid-like fashion on the facet mirror. In this case, too, an angle relationship between the coordinates of the facet mirror and the coordinates of the object field can once again be present at an angle of between 10° and 80°, in a manner corresponding to the angle ranges and angle values which were already discussed above in the context of the individual mirror unit embodiment of the second facet mirror.

The number of individual mirror units or second facets belonging to a respective one of the pre-tilt types can be such that they do not differ by more than 50%. A difference can be smaller; for example, it can be no more than 40%, no more than 30%, no more than 25%, no more than 20%, no more than 15%, no more than 10%, no more than 5%, no more than 2% or else no more than 1%. In the limit case, the number of individual mirror units or of second facets which belong to different pre-tilt types are the same. In the further limit case, each of the various pre-tilt types has exactly the same number of individual mirror units or second facets. When making available appropriate numbers of individual mirror units or second facets that belong to one of the pre-tilt types in each case, it is possible to take account of the size of initial surface regions on a first facet mirror of an illumination optical unit, to which the facet mirror belongs as a further facet mirror. Such an initial surface region serves to guide illumination light component beams within the illumination optical unit, in each case over one pre-tilt type of the second facet mirror. A number of individual mirrors of the first facet mirror are present within the respective initial surface region. For example, the number of second facets of the respective pre-tilt type can be proportional to the number of individual mirrors in the associated initial surface region. When using the second facet mirror within a specular reflector, each second facet can be weighted by a maximum partial field size that can be supported by the respective second facet, wherein this weight is then included in a determination of the number of second facets of the respective pre-tilt type made available. Appropriately ascertained weighted sums can be proportional to the number of illuminated individual mirrors of the first facet mirror within the respective initial surface region.

In the case of the embodiment with monolithic second facets, too, the number of second facets that belong to one of the pre-tilt types in each case can be similar and for example differ by no more than 10%, by no more than 5%, by no more than 2% or else by no more than 1%, or this number can be exactly equal.

An arrangement of the initial surface regions according to embodiments can take account of a folding geometry of a guidance of the illumination light through the illumination optical unit and otherwise can have corresponding desirable features as already explained above. A corresponding subdivision of the initial surface regions along the object displacement coordinate allows an embodiment of the respective initial surface region with a smaller extent along the object displacement coordinate in comparison with the overall extent of the first facet mirror along the object displacement coordinate, and so this results in a corresponding angle of incidence interval reduction for the associated coating types.

Overlapping initial surface regions according to embodiments can increase an assignment flexibility between the mirrors or facets of the two facet mirrors, and this increases degrees of freedom in the case of desired light mixing.

The initial surface regions can have a rectangular, elliptical or else circular boundary. A polygonal boundary of the initial surface regions is also possible. The initial surface regions can have an aspect ratio that differs from 1 and can for example have a smaller extent along the object displacement coordinate than perpendicular thereto. This can lead to a desired reduction of angle of incidence intervals of the illumination light on the second facet mirror. Such initial surface regions with an aspect ratio differing from 1 can also be present on the first facet mirror in mixed form, i.e. for example as at least one horizontal and at least one vertical ellipse. This can be used to create overlap regions that are as large as possible between adjacent initial surface regions, and this increases the degrees of freedom of an assignment of first to second facets within the illumination optical unit for the purpose of specifying an appropriate illumination setting, and thus increases the possibilities for a desired mixing of the illumination light.

According to what was already explained above, tilt angle range ratios of the individual mirrors that differ from 1 can be used to adapt to the shape of the respective initial surface region.

For example, an aspect ratio between the tilt angle ranges about various axes of rotation or tilt axes of the respective individual mirror can be adapted to the aspect ratio of the initial surface region to be covered.

The features of an illumination system according to the disclosure, an optical system according to the disclosure of a projection exposure apparatus according to the disclosure, of a production method according to according to the disclosure, and of a microstructured or nanostructured component according to the disclosure can correspond to those which have already been explained above with reference to the illumination optical unit. The component produced may be a semiconductor element, especially a microchip, such as a memory chip.

### BRIEF DESCRIPTION OF THE DRAWINGS

Exemplary embodiments of the disclosure will be explained in more detail below with reference to the drawing, in which:

FIG. 1 shows very schematically, in meridional section, a projection exposure apparatus for EUV microlithography, having a light source, an illumination optical unit and a projection optical unit, wherein a plan view of an object field of the projection exposure apparatus is depicted in an insert;

FIG. 2 shows schematically and likewise in meridional section a beam path of selected individual rays of illumination light within the illumination optical unit according to FIG. 1, proceeding from an intermediate focus through to a reticle or object arranged in the object plane of the projection optical unit in the region of the illumination or object field;

FIG. 3 shows a plan view of a first facet mirror of the illumination optical unit, which is arranged in a field plane of the illumination optical unit and in an illumination far field of the light source and which is also referred to as a field facet mirror, wherein an array arrangement of individual mirror units, in each case formed from a sub-array, not visible in FIG. 1, of individual mirrors of the first facet mirror, is depicted;

FIG. 4 shows, still schematically but in comparison with FIG. 3 in an enlarged, exemplary and more detailed manner, one of the individual mirror units embodied as sub-array of the individual mirrors;

FIG. 5 shows a plan view of an illumination specification facet mirror of the illumination optical unit, the mirror being arranged at a distance from a pupil plane of the illumination optical unit and also being referred to as second facet mirror;

FIG. 6 schematically shows, once again in a plan view of an embodiment of the first facet mirror of the illumination optical unit, a variant of a column-by-column assignment of the individual mirrors of a variant of the first facet mirror to field heights x of the object field in which the object is arrangeable, wherein the column-by-column assignment is depicted in idealized fashion and the assignment of the individual mirrors to the field heights x leads to a total of eight individual mirror columns, wherein the column-by-column assignment is such that a border between two adjacent central individual mirror columns runs through a centre of an overall individual mirror arrangement of the first facet mirror;

FIG. 7 shows an excerpt according to detail VII in FIG. 6, wherein, in addition and in a manner deviating from the idealized representation of FIG. 6, an assignment of illuminated individual mirror groups on the first facet mirror is singled out in detail for the case of a y-dipole illumination setting of the illumination optical unit, the individual mirror groups constituting virtual first facets which are assigned second facets of the second facet mirror via illumination channels, wherein some of the individual mirror groups (virtual first facets) use free spaces within the column-by-column assignment according to FIG. 6 which are not used within the scope of the column-by-column assignment, i.e. do not correspond to an ideal reference column assignment;

FIG. 8 shows, in an illustration similar to FIG. 7, the detailed view VIII in FIG. 6;

FIG. 9 shows a diagram showing a correlation N (ordinate) of the field height coordinates x within the respective column of the first facet mirror (abscissa) when the “y-dipole” illumination setting according to FIGS. 6 to 8 is set;

FIG. 10 shows, in an illustration similar to FIG. 7, the detailed view X in FIG. 6, for the case of a column-by-column assignment for an annular illumination setting set by way of tilt positions of the two facet mirrors of the illumination optical unit;

FIG. 11 shows, in an illustration similar to FIG. 7, the detailed view XI in FIG. 6;

FIG. 12 shows a diagram showing a correlation (ordinate) of the field height coordinates within the respective column of the first facet mirror (abscissa) when the “annular” illumination setting according to FIGS. 10 and 11 is set;

FIG. 13 shows, in an illustration similar to FIG. 7, the detailed view XIII in FIG. 6, for the case of a column-by-column assignment for an “x-dipole” illumination setting set by way of tilt positions of the two facet mirrors of the illumination optical unit;

FIG. 14 shows, in an illustration similar to FIG. 7, the detailed view XIV in FIG. 6;

FIG. 15 shows a diagram showing a correlation (ordinate) of the field height coordinates within the respective column of the first facet mirror (abscissa) when the “x-dipole” illumination setting according to FIGS. 13 and 14 is set;

FIG. 16 shows, in an illustration similar to FIG. 6, a column-by-column assignment of the first facets to field heights (x-coordinate) of an object field with a smaller field height extent in comparison with FIG. 6, such that a total of eleven individual mirror columns arise in the case of the column-by-column assignment;

FIG. 17 shows, in an illustration similar to FIG. 6, a column-by-column assignment of the individual mirrors of the first facet mirror to field heights of the object field, wherein the column-by-column assignment is such that this yields a central individual mirror column;

FIGS. 18A-18T show different illumination settings that can be set using the illumination optical unit according to FIGS. 1 to 5, depicted as regions of the pupil of the projection optical unit of the projection exposure apparatus impinged upon by illumination light;

FIG. 19 shows, in a diagram, a proportion A (ordinate) of all column-by-column assigned individual mirrors of the first facet mirror which are below a given maximum deviation D, plotted on the abscissa, from an ideal field height assignment (deviation Δx=0), i.e. deviate by less than the maximum deviation of the field height coordinate of an ideal reference column assignment of the individual mirrors of the first facet mirror, depicted for illumination settings according to FIG. 18;

FIG. 20 shows, in an illustration similar to FIG. 3, the first facet mirror of the illumination optical unit, wherein the individual mirror units which belong to a specific pre-tilt type of two different pre-tilt types that differ in respect of the pre-tilt angle are hatched differently;

FIG. 21 shows, in an illustration similar to FIG. 5, a plan view of the second facet mirror, wherein target surface regions of the second facet mirror which can be illuminated using a respective pre-tilt type of the individual mirror units of the first facet mirror are hatched differently once again;

FIG. 22 shows, in an illustration similar to FIG. 20, the first facet mirror of the illumination optical unit once again, wherein individual mirror units of different coating types optimized for different angles of incidence of the illumination light are hatched differently, with the result that a combination from the pre-tilt types according to FIG. 20 and the coating types arises for the respective individual mirror units;

FIG. 23 shows, in an illustration similar to FIG. 21, differently hatched target surface regions once again, which can be impinged upon on the second facet mirror using the individual mirror groups of the various pre-tilt and coating types according to FIG. 22;

FIG. 24 shows, in an illustration corresponding to FIG. 6, a line-by-line subdivision of the individual mirrors of the first facet mirror into three different pre-tilt types;

FIG. 25 shows, in an illustration corresponding to FIG. 21 in principle, the three target surface regions on the second facet mirror, which can be impinged upon on the second facet mirror by way of the three pre-tilt types according to FIG. 24;

FIG. 26 shows, once again in an illustration corresponding to FIG. 6, the first facet mirror with a quadrant-by-quadrant subdivision of the individual mirror into two different pre-tilt types (quadrants I/III on the one hand and quadrants II/IV on the other hand);

FIG. 27 shows, in an illustration corresponding to FIG. 22, a further variant of a subdivision of the individual mirrors of the first facet mirror into different coating types;

FIG. 28 shows, in an illustration corresponding to FIGS. 20, 22, 24 and 27, the subdivision of the individual mirrors of the first facet mirror into firstly pre-tilt types and secondly coating types;

FIG. 29 shows, in an illustration corresponding to FIG. 22, a further variant of a subdivision of the individual mirrors of the first facet mirror into different coating types;

FIG. 30 shows, in an illustration corresponding to FIGS. 20, 22, 24 and 27, the subdivision of the individual mirrors of the first facet mirror into firstly pre-tilt types and secondly coating types;

FIG. 31 shows, in an illustration similar to FIG. 27 or 29, a further variant of a subdivision of the individual mirrors of the first facet mirror, column by column in this case, into different coating types;

FIG. 32 once again shows a plan view of an embodiment of the first facet mirror of the illumination optical unit, wherein a total of four initial surface regions are embodied for the purpose of guiding illumination light component beams via the corresponding alignment channels via in each case one pre-tilt type of second facets of the second facet mirror, wherein the pre-tilt types once again differ in respect of the base tilt angles on the second facets, for which the respective pre-tilt types are optimized;

FIG. 33 shows a further embodiment of a second facet mirror in a plan view corresponding to FIG. 5, wherein the second facet mirror comprises individual mirror units in an array arrangement which correspond to those of the first facet mirror according to FIG. 3, and wherein an assignment of the respective individual mirror units of the second facet mirror to a total of four different pre-tilt types is emphasized by different hatchings;

FIG. 34 shows, in an illustration similar to FIG. 32, a further embodiment of a subdivision of the first facet mirror into four initial surface regions, assigned to different pre-tilt types of the second facet mirror;

FIG. 35 shows, in an illustration similar to FIG. 32, a further embodiment of a subdivision of the first facet mirror into four initial surface regions, assigned to different pre-tilt types of the second facet mirror;

FIG. 36 shows, in an illustration similar to FIG. 32, a further embodiment of a subdivision of the first facet mirror into initial surface regions assigned to different pre-tilt types of the second facet mirror, wherein a subdivision into a total of five initial surface regions is shown here, the five initial surface regions being correspondingly assigned to five different pre-tilt types of the second facet mirror;

FIG. 37 shows, in an illustration similar to FIG. 32, a further embodiment of a subdivision of the first facet mirror into initial surface regions assigned to different pre-tilt types of the second facet mirror, wherein a subdivision into a total of nine initial surface regions is shown here, the nine initial surface regions being correspondingly assigned to nine different pre-tilt types of the second facet mirror;

FIG. 38 shows, in an illustration similar to FIG. 33, a subdivision of the second facet mirror into individual mirror groups which belong to five pre-tilt types;

FIG. 39 shows an excerpt from a further embodiment of the second facet mirror, embodied with monolithic second facets which in turn are thus not subdivided into individual mirrors, wherein these monolithic second facets once again belong to five pre-tilt types which are emphasized in FIG. 39 by different hatchings;

FIG. 40 shows, in an illustration similar to FIG. 39, a corresponding assignment of the monolithic second facets to a total of nine pre-tilt types, for example designed to reflect illumination light emanating from the nine initial surface regions according to FIG. 37; and

FIGS. 41 and 42 show embodiment variants of the first facet mirror with monolithic first facets, which in turn are transferred into the object field by way of respectively assigned second facets of the second facet mirror.

### DETAILED DESCRIPTION

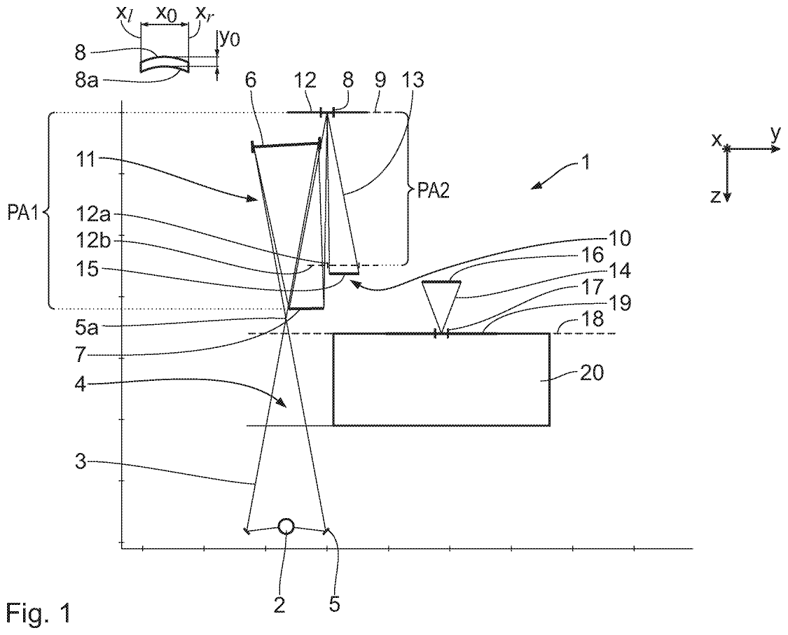

A microlithographic projection exposure apparatus 1 that is illustrated highly schematically and in meridional section in FIG. 1 has a light source 2 for illumination light 3. The light source 2 is an EUV light source which creates light in a wavelength range between 5 nm and 30 nm. Here, this may be an LPP (laser produced plasma) light source, a DPP (discharge produced plasma) light source or a synchrotron radiation-based light source, for example a free electron laser (FEL).

A transfer optical unit 4 is used to guide the illumination light 3, starting from the light source 2. The transfer optical unit has a collector 5, which is illustrated only with regards to its reflective effect in FIG. 1, and a transfer facet mirror 6, which will be described in more detail below and which is also referred to as first facet mirror or as field facet mirror. An intermediate focus 5a of the illumination light 3 is arranged between the collector 5 and the transfer facet mirror 6. A numerical aperture of the illumination light 3 in the region of the intermediate focus 5a is NA=0.182, for example. An illumination specification facet mirror 7, which is also referred to as second or further facet mirror and will also be explained in detail below, is disposed downstream of the transfer facet mirror 6 and thus the transfer optical unit 4. The optical components 5 to 7 are parts of an illumination optical unit 11 of the projection exposure apparatus 1.

The transfer facet mirror 6 is arranged in a field plane of the illumination optical unit 11.

The illumination specification facet mirror 7 of the illumination optical unit 11 is arranged at a distance from pupil planes of the illumination optical unit 11. Such an arrangement is also referred to as specular reflector. Alternatively, the illumination specification facet mirror 7 can also be arranged in the region of a pupil plane of the illumination optical unit 11, and it is referred to as a pupil facet mirror in that case.

A reticle 12 is disposed downstream of the illumination specification facet mirror 7 in the beam path of the illumination light 3 and arranged in an object plane 9 of a downstream projection optical unit 10 of the projection exposure apparatus 1. The projection optical unit 10 is a projection lens. The illumination optical unit 11 is used to illuminate an object field 8 on the reticle 12 in the object plane 9 in a defined manner. At the same time, the object field 8 represents an illumination field of the illumination optical unit 11. Generally it holds true that the illumination field is formed in such a way that the object field 8 can be arranged in the illumination field.

Like the transfer facet mirror 6 as well, the illumination specification facet mirror 7 is part of a pupil illumination unit of the illumination optical unit and serves to illuminate an entrance pupil 12a in a pupil plane 12b of the projection optical unit 10 with the illumination light 3 with a specified pupil intensity distribution. The entrance pupil 12a of the projection optical unit 10 can be arranged in the illumination beam path upstream of the object field 8 or else downstream of the object field 8. FIG. 1 shows the case in which the entrance pupil 12a is arranged in the illumination beam path downstream of the object field 8. A pupil distance PA between the second facet mirror 7 and the pupil plane 12b results in this case as the sum of a z-distance PA1 between the second facet mirror 7 and the object plane 9 and the z-distance PA2 between the object plane 9 and the pupil plane 12b. Thus, the following applies: PA=PA1+PA2. Alternatively, the pupil distance PA can also be measured in the beam direction.

In order to facilitate the representation of positional relationships, a Cartesian xyz-coordinate system will be used hereinafter. The x-direction runs perpendicularly to the plane of the drawing into the latter in FIG. 1. In FIG. 1, the y-direction runs to the right. The z-direction runs downwards in FIG. 1. Coordinate systems used in the drawing have x-axes running parallel to one another in each case. The course of a z-axis of the coordinate systems follows a respective principal direction of the illumination light 3 within the respective figure under consideration.

The object field 8 has an arcuate or partly circular shape and is delimited by two mutually parallel circle arcs and two straight side edges which run in the y-direction with a length y₀ and are at a distance x₀ from one another in the x-direction. The aspect ratio x₀/y₀ is 13 to 1. An insert in FIG. 1 shows a plan view of the object field 8, this plan view not being true to scale. A boundary shape 8a is arcuate. In an alternative and likewise possible object field 8, the boundary shape thereof is rectangular, likewise with aspect ratio x₀/y₀.

The reticle 12 is displaced through the object field 8 in an object displacement direction y during a projection exposure.

The projection optical unit 10 is indicated only in part and highly schematically in FIG. 1. An object field-side numerical aperture 13 and an image field-side numerical aperture 14 of the projection optical unit 10 are illustrated. The image field-side numerical aperture 14 can be in the range between 0.2 and 0.8 and can be 0.3, 0.33, 0.4, 0.45, 0.5, 0.55, 0.6, 0.65, 0.7 or else 0.75, for example. Further optical components (not illustrated in FIG. 1) of the projection optical unit 10 for guiding the illumination light 3 between indicated optical components 15, 16 of the projection optical unit 10 are situated between these optical components 15, 16, which may be embodied for example as mirrors that are reflective for the EUV illumination light 3.

The projection optical unit 10 images the object field 8 into an image field 17 in an image plane 18 on a wafer 19, which, like the reticle 12 as well, is carried by a holder (not depicted in detail). Both the reticle holder and the wafer holder are displaceable both in the x-direction and in the y-direction using corresponding displacement drives. An installation space of the wafer holder is illustrated as a rectangular box at 20 in FIG. 1. The installation space 20 is cuboid with an extent in x-, y- and z-directions that is dependent on the component parts to be accommodated herein. The installation space 20 has, for example, proceeding from the centre of the image field 17, an extension of 1 m in the x-direction and in the y-direction. In the z-direction, too, the installation space 20 has, proceeding from the image plane 18, an extension of 1 m, for example. The illumination light 3 has to be guided in the illumination optical unit 11 and the projection optical unit 10 in such a way that it is in each case guided past the installation space 20.

The transfer facet mirror 6 has a multiplicity of transfer facets 21, which are also referred to as first facets. The transfer facet mirror 6 can be embodied as a MEMS mirror. The transfer facets 21 are individual mirrors which are switchable at least between two tilt positions and are embodied as micromirrors. The transfer facets 21 may be embodied as micromirrors tiltable in a driven manner about two rotation axes perpendicular to one another.

Possible switching amplitudes of the individual mirrors 21 about the two axes of rotation can differ from one another. For example, a tilt angle range Δx about a tilt axis or axis of rotation along the x-coordinate can be greater or smaller than a tilt angle range Δy about a tilt axis or axis of rotation along the y-coordinate should a reflection surface of the individual mirror 21 be arranged in an xy-plane. Thus, a directionally dependent tilt angle range may be present. A ratio between these tilt angle ranges can be in the range between 1.1 and 10. For example, the respective individual mirror can comprise a mount for pivotable bearing of the mirror body thereof, having two degrees of tilt freedom and having an actuator device for pivoting the mirror body in such a way that the mirror body has a directionally dependent tilt angle range.

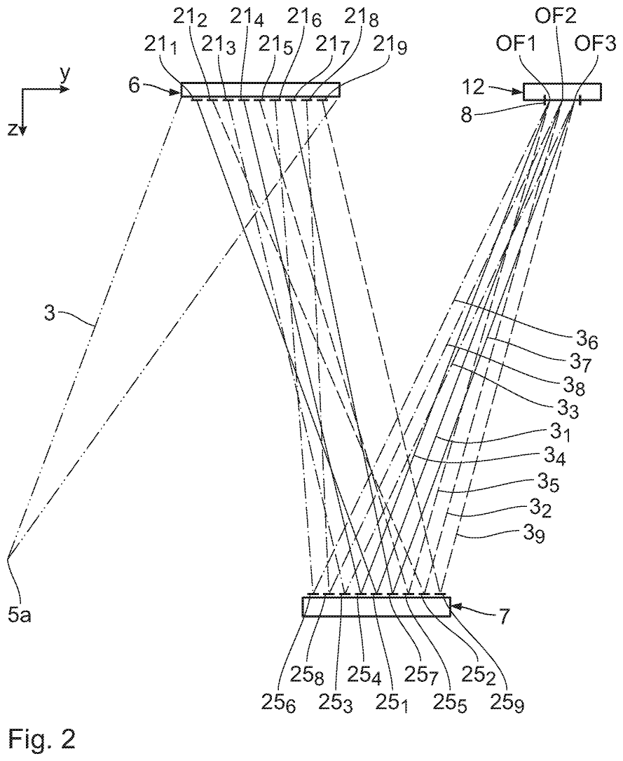

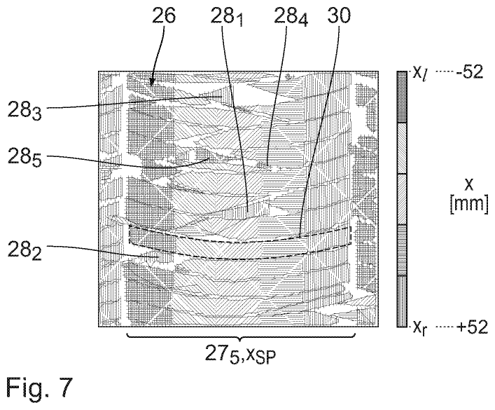

Of these individual mirrors or transfer facets 21, a line having a total of nine transfer facets 21 indexed from left to right by 21₁ to 21₉ in FIG. 2 is illustrated schematically in the yz-sectional view according to FIG. 2. In actual fact, the transfer facet mirror 6 has a significantly greater multiplicity of the transfer facets 21. The transfer facets 21 are grouped into a plurality of transfer facet groups not illustrated in detail in FIG. 2 (cf., in this respect, also FIGS. 7 and 13 for example). These transfer facet groups are also referred to as individual mirror groups, as virtual field facets or as virtual facet groups.

Each of the transfer facet groups guides a component of the illumination light 3, which is also referred to as an illumination light component beam, via an illumination channel for partial or complete illumination of the object field 8. Via the illumination channel and an illumination light component beam 3ᵢ guided via the latter, exactly one illumination specification facet 25 of the illumination specification facet mirror 7 is assigned in each case to one of the individual mirror groups or transfer facet groups. In principle, each of the illumination specification facets 25 may for their part in turn be constructed from a plurality of individual mirrors. The illumination specification facets 25 are also referred to hereinafter as second facets. To the extent that the second facet mirror 7 is arranged in the region of a pupil plane of the illumination optical unit 11, the illumination specification facets 25 are also referred to as a pupil facets.

An individual mirror group is a group of individual mirrors 21 of the first facet mirror 6 which are imaged into the object field 8 by the same second facet 25.

For further details of possible embodiments of the transfer facet mirror 6 and the projection optical unit 10, reference is made to WO 2010/099 807 A.

At least some of the illumination specification facets 25 illuminate only a partial zone or partial field of the object field 8. The partial fields are shaped very individually and, moreover, depend on the desired illumination direction distribution (pupil shape) in the object field 8, i.e. the illumination setting. The illumination specification facets 25 are therefore illuminated by very differently shaped virtual field facets, the shape of which corresponds precisely to the shape of the respective partial field to be illuminated. Moreover, each illumination specification facet 25 contributes to different regions of the pupil depending on the location in the object field 8.

The illumination specification facet mirror 7 may be embodied as an MEMS mirror, especially if each of the illumination specification facets 25 is constructed from a plurality of individual mirrors. The illumination specification facets 25 are micromirrors switchable between at least two tilt positions. The illumination specification facets 25 are embodied as micromirrors which are tiltable in a driven manner about two mutually perpendicular tilt axes in two dimensions, for example in continuous and independent fashion, i.e. the micromirrors may be positioned into a multiplicity of different tilt positions.

The explanations given above with regards to the individual mirrors 21 of the transfer facet mirror 6 apply to the tilt angle ranges Δx, Δy about the tilt axes or axes of rotation of these micromirrors or individual mirrors of the illumination specification facets 25. Directionally dependent tilt angle ranges may also be present here.

One example of a specified assignment of individual transfer facets 21 to the illumination specification facets 25 is depicted in FIG. 2. The illumination specification facets 25 in each case assigned to the transfer facets 21₁ to 21₉ are indexed according to this assignment. On account of this assignment, the illumination specification facets 25 are illuminated from left to right in the following order: 25₆, 25₈, 25₃, 25₄, 25₁, 25₇, 25₅, 25₂ and 25₉.

The indices 6, 8 and 3 of the facets 21, 25 include three illumination channels 3₆, 3₈ and 3₃ which illuminate three object field points OF1, OF2, OF3 from a first illumination direction, the object field points being numbered from left to right in FIG. 2. The indices 4, 1 and 7 of the facets 21, 25 belong to three further illumination channels 3₄, 3₁, 3₇ which illuminate the three object field points OF1 to OF3 from a second illumination direction. The indices 5, 2 and 9 of the facets 21, 25 belong to three further illumination channels 3₅, 3₂, 3₉ which illuminate the three object field points OF1 to OF3 from a third illumination direction. The illumination channels 3₁ to 3₉ are assigned corresponding illumination light component beams 3₁ to 3₉.

The illumination directions assigned to
the illumination channels 3₆, 3₈, 3₃,
the illumination channels 3₄, 3₁, 3₇ and
the illumination channels 3₅, 3₂, 3₉
   are identical in each case. The assignment of the transfer facets 21 to the illumination specification facets 25 is therefore such that this results in a telecentric illumination of the object field 8 in the case of the illumination example illustrated pictorially.

The object field 8 can be illuminated via the transmission facet mirror 6 and the illumination specification facet mirror 7 in the style of a specular reflector. The principle of the specular reflector is known from US 2006/0132747 A1.

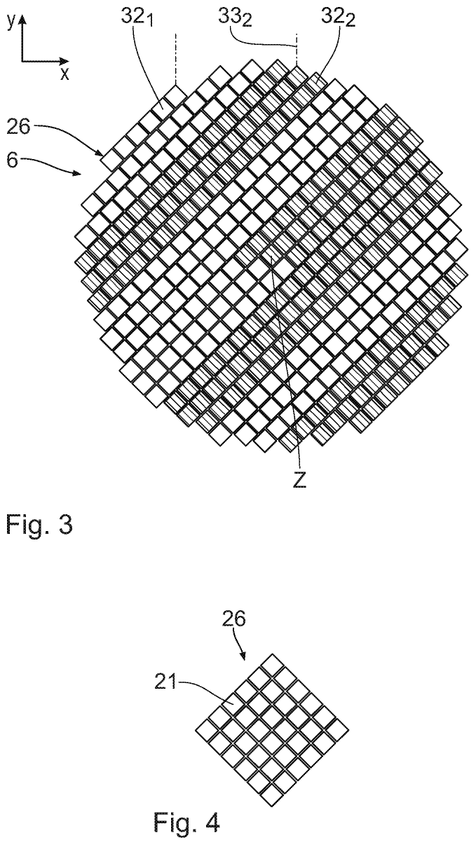

FIG. 3 shows a plan view of the first facet mirror 6. The latter has a regular array arrangement of individual mirror units 26, which are bounded by squares in FIG. 3. Each of the individual mirror units 26 is embodied as a sub-array of N×M of the individual mirrors 21. This sub-array has a plurality of array lines which extend along a line direction that corresponds to an angle bisector of the xy-coordinate system. Some of the mutually adjacent array lines are offset from one another by a proportion of an extent of one of the individual mirror units 26, for example by half of this extent of the respective individual mirror unit 26 along the array line. Depending on an embodiment of the facet mirror 6, it is possible to manage entirely without such an offset, and so this results in an array arrangement constructed entirely of lines and columns. Alternatively, all array lines can be offset from one another. Different absolute offset values between different adjacent array parts are possible, depending on the embodiment of the facet mirror 6 and depending on the properties placed on a positioning of the individual mirror units 26.

The first facet mirror 6 is embodied for arrangement in a used region of a far field of the light source 2.

FIG. 4 shows one of the individual mirror units 26, still schematically but with more detail. What is shown is a subdivision of the individual mirror unit 26 into the sub-array of 6×6 individual mirrors 21 in this case. Thus, each of the individual mirror units 26 has 36 of the individual mirrors 21 in the embodiment illustrated. Thus, N=6 and M=6 applies to the N×M sub-array arrangement in the example according to FIG. 4. N and M can be the same, can be different and can each be in the range between 2 and 64, for example at 4, 8, 16, 32 or 64. Other values than powers of two are also possible for N and M, for example 25 or 50. For example, a 12×12 or 24×24 sub-array is also possible.

In the embodiment depicted in FIG. 3, the first facet mirror 6 has an arrangement of the individual mirror units 26 within a circular envelope. Alternatively, the first facet mirror 6 can also comprise the individual mirror units 26 within an envelope with an elliptical, rectangular or else polygonal boundary.

In each case one of the individual mirror units 26 may contain a plurality of complete or partial individual mirror groups, which guide the illumination light 3 to different second facets 25 and which are imaged into the object field 8 in a manner superimposed on one another. The individual groups can extend over a plurality of the individual mirror units 26.

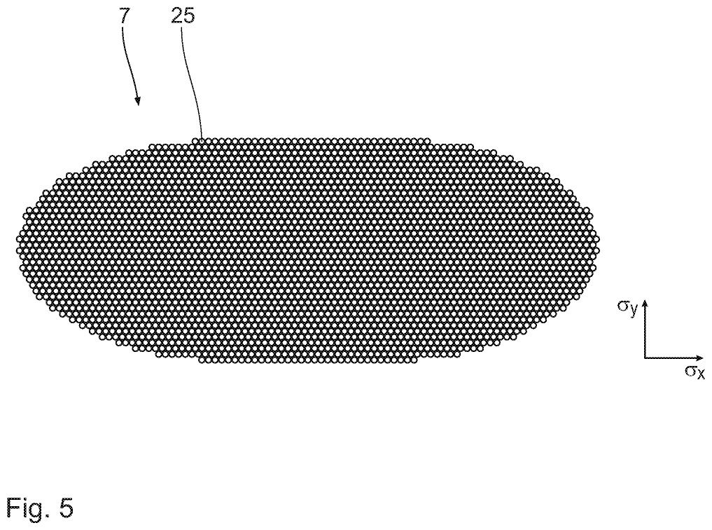

FIG. 5 shows, in turn, a plan view of the second facet mirror 7.

The second facets 25 of the second facet mirror 7 are embodied with a circular boundary and present in hexagonal close-packed form. Second facets 25 with a rectangular or polygonal boundary, for example a hexagonal boundary, are also an alternative to second facets 25 with a circular boundary. The second facets 25 can be embodied in turn as individual mirror units in the style of the individual mirror units of the first facet mirror 6 and can be subdivided into a plurality of individual mirrors in the style of the individual mirrors 21 in this case. In principle, with regards to the subdivision into individual mirrors and individual mirror units, a structure of the second facet mirror 7 can correspond to the structure of the first facet mirror 6.

In the embodiment according to FIG. 5, each of the second facets 25 can also be embodied as a monolithic facet.

In the second facet mirror 7, the second facets 25 are arranged within an envelope with an elliptical boundary. Alternatively, other envelope shapes are also possible here, for example a circular envelope, a rectangular envelope and also an envelope with a polygonal edge.

Selected ones of the second facets 25 are assigned to an illumination light component beam 3ᵢ and hence assigned to an individual mirror group of the individual mirrors 21 of the first facet mirror 6.

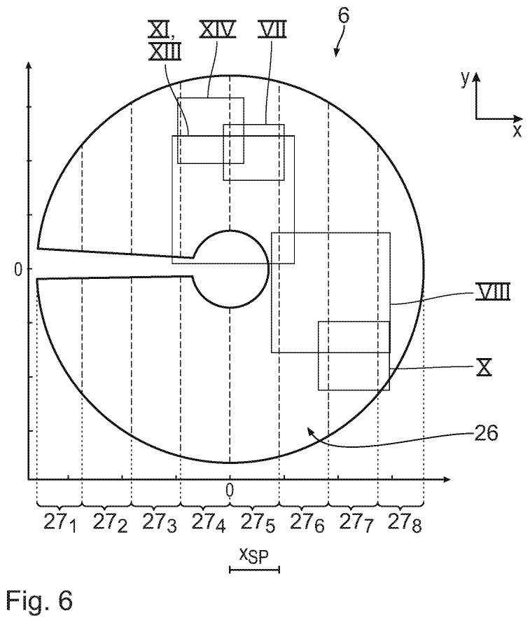

An assignment of the individual mirrors of the first facet mirror 6 to field heights x of the object field 8 is illustrated in FIG. 6 and the detailed excerpt enlargements VII, VIII, X, XI, XIII, XIV in FIG. 6, which are reproduced as FIGS. 7, 8, 10, 11, 13, 14. The field height x is perpendicular to the object displacement direction y. In FIG. 6, an edge contour which has an approximately keyhole-shaped incision at the “9 o'clock” position shows an area of the first facet mirror 6 that is usable for guiding the illumination light 3.

Like in FIG. 3, the distinct individual mirrors 21 are not visible in FIGS. 6, 7, 8, 10, 11, 13, 14; at best, it is possible to identify the square individual mirror units 26 with a rhomboid arrangement. In an overarching manner, the individual mirror groups may contain individual mirrors 21 from multiple adjacent individual mirror units 26.

In the first facet mirror 6 according to FIGS. 6, 7, 8, 10, 11, 13, 14, the individual mirror units are arranged in the form of a sub-array with array lines and array columns in each case arranged in a manner tilted through 45° with respect to the xy-coordinate axes. In the line direction, there is no offset of the individual mirror units 26 between adjacent array lines, and so this results in uninterrupted continuous array lines and uninterrupted continuous array columns.

The assignment of the individual mirrors 21, which are not resolved within the individual mirror units 26 in the drawings of FIGS. 7, 8, 10, 11, 13, 14, to the respective field height x is represented by changing hatchings in FIGS. 7, 8, 10, 11, 13, 14, wherein each of the hatchings stands for a certain field height x between a left field edge xₗ (cf. the insert in FIG. 1 as well) and a right field edge xᵣ, measured between which is an overall original image field width x_{SP} that is imaged into the object field width x₀ using the transfer optical unit disposed downstream of the first facet mirror 6 within the illumination optical unit 11, wherein the field height x, along which the object field width x₀ is measured, runs perpendicular to the object displacement direction y. In the hatching key to the right of FIG. 7, this original image field height x is reproduced between values of “−52 mm” and “+52 mm”, i.e. over the entire field width of the object field 8. In the example corresponding to the individual mirror assignment according to FIGS. 7, 8, 10, 11, 13, 14, the object field 8 has a field width x₀ of 104 mm along the x-coordinate.

A respective illumination light component beam 3ᵢ guided over a correspondingly assigned individual mirror is incident on the object field at the respectively assigned field height x.

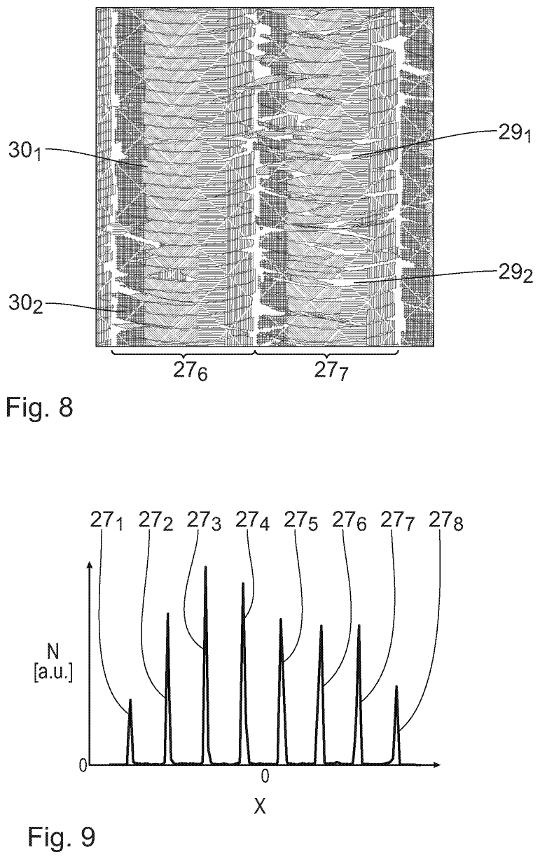

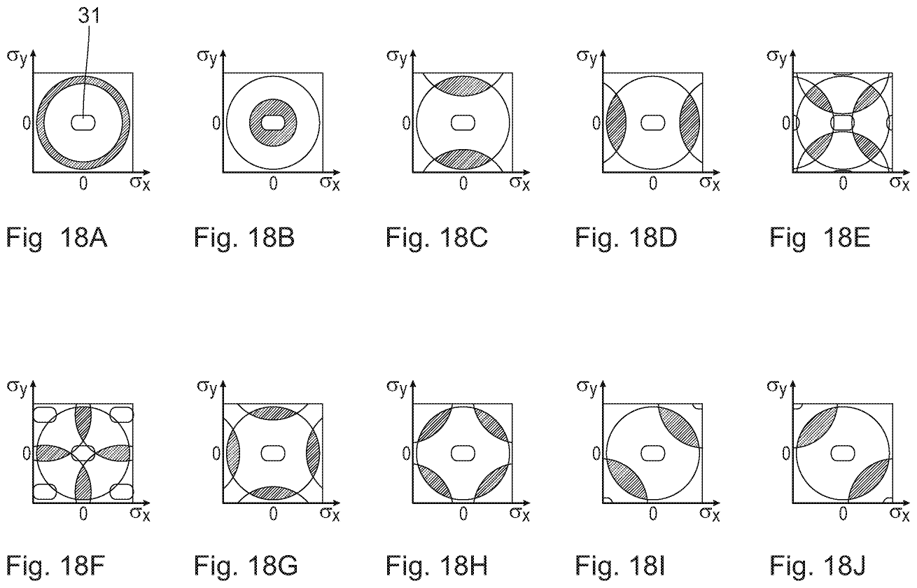

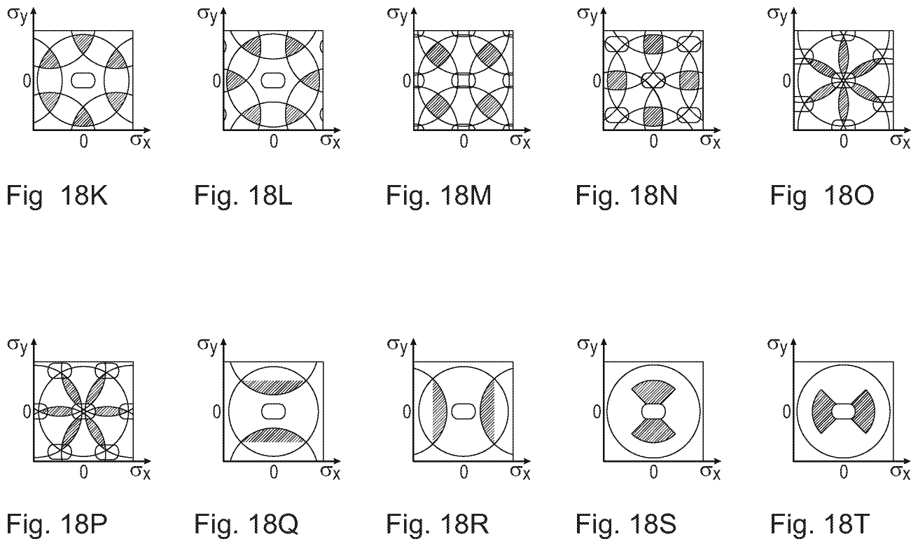

The assignment of the individual mirrors of the individual mirror units 26 to the respective field height x is reproduced in FIGS. 7 and 8 for a “y-dipole leaflets” illumination angle distribution, the illumination intensity distribution of which in a pupil plane of the projection optical unit 10 that is conjugate to the entrance pupil plane 12a being reproduced in FIG. 18C.

In this case, FIG. 6 illustrates a rough, idealized assignment of the individual mirrors of the individual mirror units 26 to the respective field height x, subdivided into a total of eight individual mirror columns 27₁ to 27₈ which run along a y-coordinate of the first facet mirror 6. This idealized column-by-column individual assignment corresponds to a reference column arrangement or reference column assignment of the individual mirrors of the first facet mirror.

At the transition between two adjacent individual mirror columns 27ᵢ, 27ᵢ₊₁, the assignment of the respective individual mirror changes from one field edge of the object field 8 to the opposite field edge of the object field 8.

A width, as measured along the x-coordinate of the field facet mirror 6, of the respective individual mirror column 27ᵢ imaged into the x-coordinate of the object field 8 corresponds to the original image field width x_{SP}. Thus, the original image field width x_{SP} corresponds to the object field width x₀ multiplied by the reciprocal imaging scale of the imaging of the individual mirror groups into the object field 8.

FIG. 7 shows the individual mirror assignment in more detail (detail VII in FIG. 6). FIG. 7 shows a y-excerpt of the first facet mirror 6 over an entire x-width of the individual mirror column 27₅. It is evident that, in addition to the fundamental column-by-column assignment within the individual mirror columns 27ᵢ, the assignment of the individual mirrors of the individual mirror units 26 to the respective field heights x also contains portions 28ᵢ in which the column-by-column assignment according to the individual mirror columns 27ᵢ is not observed. The depicted portions 28₁ to 28₃ show respective groups of individual mirrors assigned to field heights in the region of the left field edge xₗ. In turn, the portions 28₄ and 28₅ are assigned to field heights in the region of the right field edge xᵣ. These portions 28ᵢ are also referred to as exceptional portions. These exceptional portions 28ᵢ can still be used to fill gaps in the regular, column-by-column individual mirror assignment in order to optimize an overall proportion of the individual mirrors used for an illumination light impingement and thus optimize a reflection efficiency of the first facet mirror 6.

The individual mirror columns 27ᵢ can also be understood as regular portions of the assignment of the individual mirrors of the first facet mirror 6.

At least 80% of the individual mirrors within the individual mirror column 27₅ of the excerpt of the first facet mirror 6 depicted in FIG. 7 follow the column-by-column assignment according to the individual mirror column 27₅, i.e. the reference column assignment. Thus, a sum of the areas of the exceptional portions 28ᵢ is no more than 20% of the section area of the individual mirror column 27₅ depicted in FIG. 7.

A complete individual mirror group 30 which is imaged into the object field 8 via the second facet mirror 7 in the event of illumination is singled out by way of example in FIG. 7 using a dashed boundary. The sequence of hatchings between the field height towards the left field edge xₗ and the field height towards the right field edge xᵣ can be tracked using this individual mirror group 30. Thus the individual mirror group 30 represents an original image of the object field 8.

FIG. 8 in turn shows an excerpt enlargement of the assignment according to FIG. 6, in accordance with the detail VIII therein. For example, two y-sections of the individual mirror columns 27₆ and 27₇ are shown. A plurality of portions 29ᵢ (29₁, 29₂) which represent neither regular portions nor exceptional portions and which are not used for guiding the illumination light 3 are illustrated within the individual mirror column 27₇ for example.

Two exemplary, complete individual mirror groups 30₁ and 30₂, which are each imaged into the entire object field in the event of illumination, are also singled out in FIG. 8.

FIG. 9 shows a correlation N of an assignment of the individual mirrors 21 of the first facet mirror 6 to the respective individual mirror column 27ᵢ in the event of the y-dipole leaflet illumination setting according to FIG. 18C. The correlation N shown is between the field height assignments of the individual mirrors within the regular individual mirror columns 27ᵢ and the exceptional portions 28ᵢ within the total of eight individual mirror columns 27₁ to 27₈. The respective x-coordinate within the respective individual mirror column 27ᵢ is plotted to the right and a number N of individual mirrors 21 in which the respective correlation is applicable, as a measure for the correlation, is plotted upwardly.

The respective maxima in FIG. 9 illustrate the numbers N of those individual mirrors 27ᵢ in which the assignment is perfect, i.e. which belong to the regular portions within the individual mirror columns 27ᵢ. In the x-direction, only a few individual mirrors are spaced apart from these ideal correlations within the individual mirror columns 27ᵢ by more than one fifth of the original image field width of the object field 8.

The correlation curve in each case drops to a plateau value close to zero between the maxima of the correlation representation assigned to the respective individual mirror columns 27ᵢ according to FIG. 9.

The column-by-column assignment of the individual mirrors 21 into the individual mirror groups of the first facet mirror 6 which guide the illumination light component beams 3ᵢ is such that more than 80% of the individual mirrors 21 deviate by less than 40% of an original image field width x_{SP} from the field height coordinate x of the reference column assignment, formed by the individual mirror columns 27ᵢ, of the individual mirror groups of the first facet mirror 6.

In the case of the y-dipole leaflet illumination angle distribution, for which the assignment corresponding to FIGS. 7 to 8 is available and which serves as an example of a multi-pole illumination angle distribution, the column-by-column arrangement of the individual mirror groups of the first facet mirror 6 is even such that more than 80% of the individual mirrors deviate by less than 20%, and for example by less than 10%, of the original image field width x_{SP} from field height coordinates x of the reference column assignment of the individual mirror columns 27ᵢ of the first facet mirror 6.

This assignment condition of a minimum number of individual mirror groups of the first facet mirror 6 which deviate from the field height coordinate x of the reference column arrangement of the individual mirror columns 27ᵢ of the first facet mirror 6 by less than a limit percentage of an original image field width x_{SP} applies separately to each of the facet columns 27ᵢ in the case of the assignment explained above on the basis of FIGS. 6 to 8.

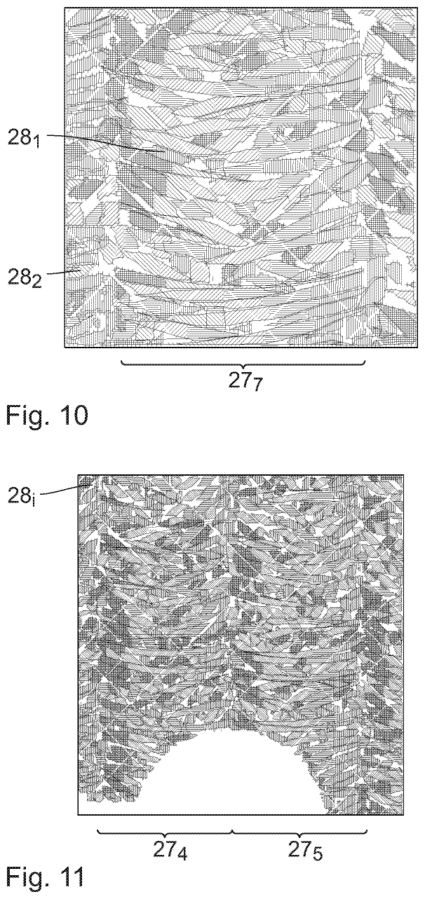

FIGS. 10 to 12, which in principle correspond to FIGS. 7 to 9, are used to describe the assignment of the individual mirrors 21 to the field heights x for a further example of an “annular illumination setting” below, the desired illumination intensity distribution of which in a pupil plane of the projection optical unit 10 being reproduced in FIG. 18A.

Since this illumination setting according to FIG. 18A comprises very narrow illuminated sections over broad sections, especially along a pupil coordinate σₓ, this results in a significantly larger fragmentation of individual mirror groups on the field facet mirror 6 which are assigned to respective illumination light component beams.

FIG. 10 shows the detail X of the field facet mirror 6 according to FIG. 6. When compared to the assignment according to FIGS. 7 and 8 for the dipole illumination setting, the number of exceptional portions 28ᵢ which do not correspond to the regular assignment according to the individual mirror columns 27ᵢ has been increased significantly in this assignment for the annular illumination setting. Nevertheless, the regular assignment over the individual mirror column 27₇ can still be clearly identified, even in FIG. 10. Even in this extreme case of the annular illumination setting, the column-by-column arrangement of the individual mirror groups of the first facet mirror 6 is still such that more than 80% of the individual mirrors 21 deviate by less than 40% of the original image field width x_{SP} from the field height coordinate x of the reference column assignment of the individual mirror columns 27ᵢ of the first facet mirror 6.

FIG. 11 shows the detailed section XI of the field facet mirror 6 according to FIG. 6 with y-sections of the individual mirror columns 27₄ and 27₅. A comparatively strongly fragmented subdivision with, in relative terms, many exceptional portions 28ᵢ is also identifiable in this case, with the regular assignment over the individual mirror columns still being clearly identifiable at the same time.

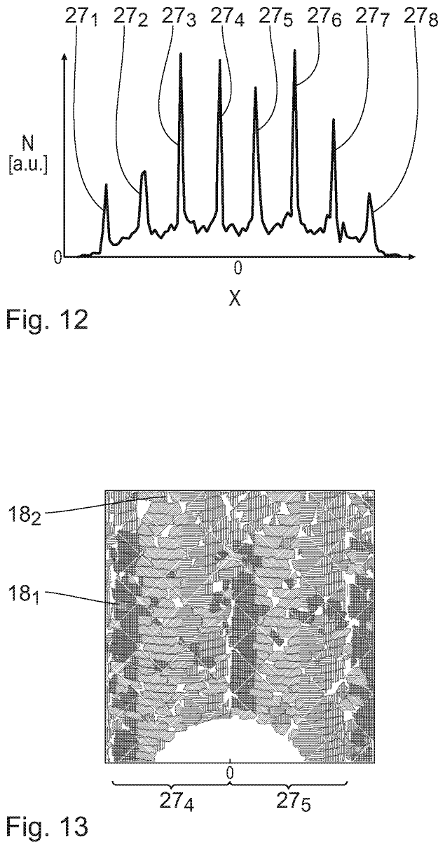

In a graph similar to FIG. 9, FIG. 12 shows the correlation N of the individual mirrors 21 to the individual mirror columns 27₁ to 27₈. The greater fragmentation with the greater proportion of exceptional portions 28ᵢ leads to the maximum number N of the individual mirrors 21 that form the peaks with regards to the individual mirror columns 27₁ being lower than in the correlation according to FIG. 9 by approximately a factor of 2.5. Moreover, a significant background formed by the individual mirrors 21 of the exceptional portions 28ᵢ is identifiable between these peaks that are assigned to the individual mirror columns 27ᵢ.

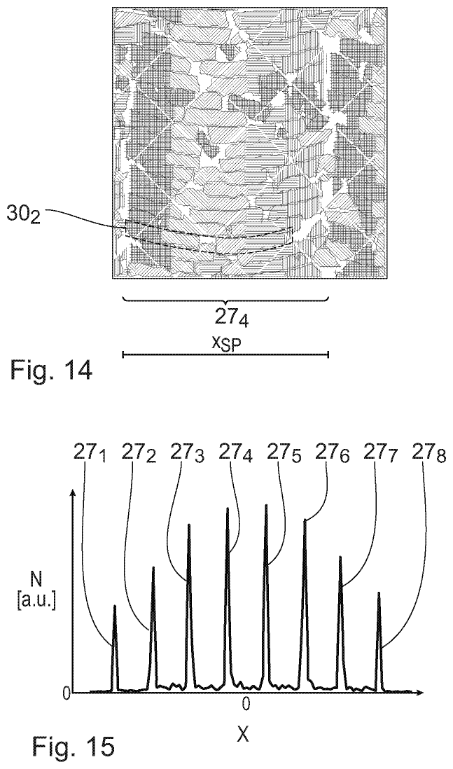

In illustrations similar to FIGS. 6 to 8 and also 10 and 11, FIGS. 13 and 14 show the individual mirror/field height assignment in further detailed sections XIII and XIV of the field facet mirror 6 according to FIG. 6 for an “x-dipole” illumination setting according to FIG. 18D.

In this case, the number of exceptional portions 18ᵢ (18₁, 18₂) is greatly reduced in comparison with the annular illumination setting according to FIGS. 10 to 12. Individual mirror groups 30ᵢ, which transfer corresponding illumination light component beams into the object field 8, are identifiable in FIG. 13. On account of the imaging into the object field 8, these individual mirror groups 30ᵢ have a similarly curved shape to that of the object field 8.

FIG. 13 shows a y-section of the field facet mirror 6, once again in the region of the individual mirror groups 27₄ and 27₅.

FIG. 14 shows the assignment in the region of the individual mirror column 27₄ in the detailed section XIV of FIG. 6, once again for the “x-dipole” illumination setting. Here, individual mirror groups which cover the entire original image width x_{SP} of the individual mirror column 27₄ apart from the transitions between the individual mirror units 26 are identifiable in part. In fact, these individual mirror groups are not individual mirror groups which, overall, are imaged into the object field 8 via exactly one illumination light component beam 3ᵢ and exactly one second facet 25; instead, this in fact relates to a plurality of individual mirror groups 30ᵢ which are put together like a puzzle so as to fit exactly with regards to the x-assignment of the individual mirrors 21 and which are imaged into the corresponding field heights x in corresponding partial fields of the object field 8 via different second facets 25.

Individual mirror groups 30ᵢ which are displaced from the ideal field height assignment (peak positions of the correlations) by only a comparatively small x-value are also identifiable. Such an individual mirror group is singled out at 30₂ in FIG. 14. This individual mirror group 30₂ is an example of an individual mirror group which does not belong to the reference column assignment but nevertheless fulfils the assignment condition whereby a deviation of the individual mirrors 21 belonging to this individual mirror group 30₂ from the field height coordinate x of the reference column assignment is less than 10% of the original image field width x_{SP}.

In a manner comparable to FIGS. 9 and 12, FIG. 15 shows the individual mirrors/field height assignment correlation for the case of the x-dipole illumination setting, i.e. for the individual mirror group occupancy of the field facet mirror 6 according to FIGS. 13 and 14. The correlation according to FIG. 15 is insubstantially weaker than that according to FIG. 9.

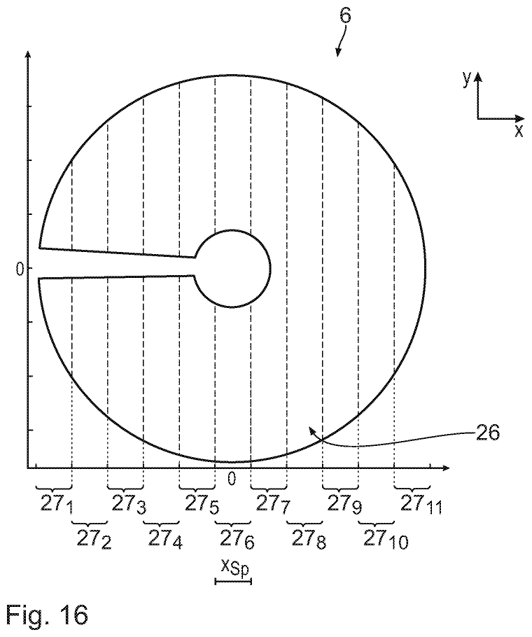

FIG. 16 shows a further example of the individual mirror/field height assignment for an object field 8 with a reduced x-object field width x₀ in comparison with the assignment according to FIG. 6. The smaller x-field width x₀ of the object field 8 leads to a correspondingly smaller original image field width x_{SP} in the arrangement plane of the field facet mirror 6 and hence to an occupancy of the field facet mirror 6, i.e. a reference column assignment, with a greater number of individual mirror columns 27ᵢ. Overall, this assignment occupancy according to FIG. 16 leads to eleven individual mirror columns 27₁ to 27₁₁.

The illumination setting applicable to the assignment according to FIG. 16 is an x-dipole setting according to FIG. 18D.

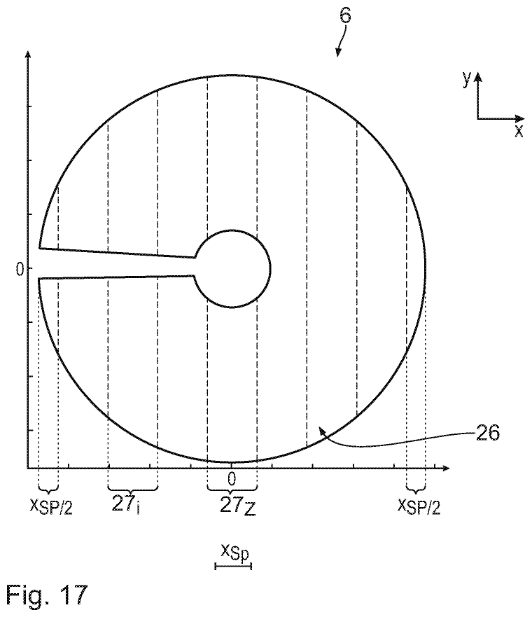

FIG. 17 shows a further individual mirror/field height assignment, once again for an object field width x₀ like in the assignment according to FIG. 6 but this time for the “bar-shaped y-dipole” illumination setting. Rectangular poles are present here instead of leaflet-shaped individual poles as in the illumination setting according to FIG. 18C. This results in an assignment distribution with, once again, a total of eight individual mirror columns, wherein the assignment according to FIG. 17 contains a central individual mirror column 27_{Z} and, on the edge in both the negative x-direction and the positive x-direction, a respective individual mirror column with half the original image field width x_{SP}/2.

In the case of the assignments explained above in the context of FIGS. 6 to 17, a proportion of individual mirrors 21 used to guide the illumination light 3 is greater than 80% and for example greater than 84% in each case.

FIG. 18 shows an overview of possible illumination settings that can be specified with the aid of the illumination optical unit 11 with an appropriate individual mirror/field height assignment of the individual mirror groups 30ᵢ that guide the illumination light component beams. An illumination intensity distribution in the region of an entrance pupil of the projection optical unit 10 is shown. An obscuration region 31, i.e. shadowing of a central pupil region of the projection optical unit 10 in the projection exposure apparatus 1, is shown centrally in the respective illumination setting.

By way of example, the following illumination settings are depicted:
FIG. 18A: An annular illumination setting with a large absolute illumination angle;
FIG. 18B: An annular illumination setting with a small absolute illumination angle;
FIG. 18C: A leaflet y-dipole illumination setting;
FIG. 18D: A leaflet x-dipole illumination setting;
FIG. 18E: A leaflet quadrupole illumination setting with illumination from the four quadrants;
FIG. 18F: A leaflet quadrupole illumination setting with illumination from the horizontal/vertical directions;
FIG. 18G: A “superposition of x-dipole and y-dipole” leaflet illumination setting;
FIG. 18H: An “18G rotated through 45°” leaflet illumination setting;
FIG. 18I: An “18C rotated through −45°” leaflet dipole illumination setting;
FIG. 18J: An “18C rotated through +45°” leaflet dipole illumination setting;
FIG. 18K: A hexapole illumination setting;
FIG. 18L: An “18K rotated through 30°” hexapole illumination setting;
FIG. 18M: A quasar illumination setting;
FIG. 18N: A C-quad illumination setting (18M rotated through 45°);
FIG. 18O: A leaflet hexapole Y-illumination setting;
FIG. 18P: A leaflet hexapole X-illumination setting (18O rotated through 30°);
FIG. 18Q: A Y-dipole illumination setting with middling illumination angles;
FIG. 18R: An X-dipole illumination setting with middling illumination angles;
FIG. 18S: A Y-dipole illumination setting with small illumination angles;
FIG. 18T: An X-dipole illumination setting with small illumination angles.

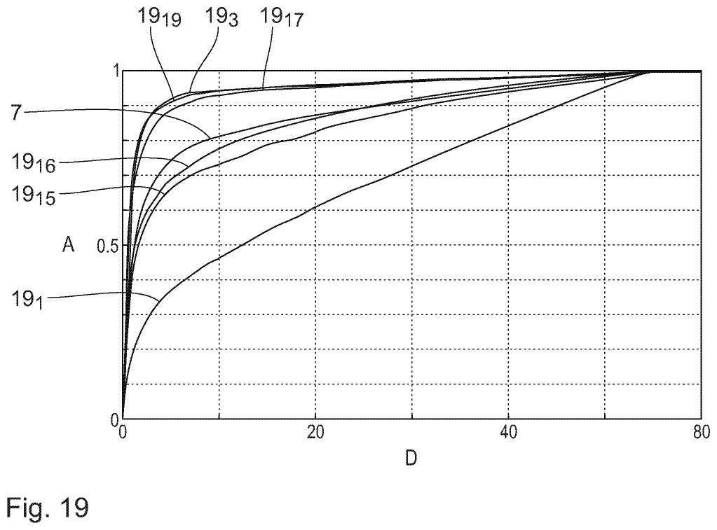

FIG. 19 shows a graph of an individual column correlation, partly assigned to the illumination settings 18A to 18T, when assigning the individual mirrors 21 to the field heights x on the facet mirror 6. The abscissa shows a deviation D of the original image position of the respective individual mirror 21 from an ideal position within the respective individual mirror column 27ᵢ. The depicted correlation curves 19ᵢ show the proportion A of individual mirrors 21 of the field facet mirror 6 that have no more than the respective deviation D specified along the abscissa.

The curve 19₁ shows the correlation for the illumination setting according to FIG. 18A, i.e. the annular illumination setting with large illumination angles, the assignment occupancy of which is also depicted in FIGS. 10 and 11. In this illumination setting according to the correlation curve 19₁, only a very small proportion of individual mirrors 21 does not deviate at all from the ideal individual mirror column position, i.e. from the reference column assignment.

The maximum deviation depicted in FIG. 19 is the original image deviation, which corresponds to half the field width x₀. Thus, for a field width x₀ of the object field 8 of 104 mm, this is the original image deviation from the object field width of 52 mm. A greater deviation than half the field width is not possible from a theoretical point of view.

What can be gathered from the curve profile of the correlation curve 19₁ in FIG. 19 is that, for the illumination setting of FIGS. 18A, 80% of the individual mirrors 21 deviate by less than 40% of the original image field width x_{SP} from the ideal individual mirror column arrangement since the correlation curve 19₁ intersects the mirror proportion value of 0.8 at approximately the value of 37 mm, which corresponds to approximately 36% of the object field width of 104 mm.

For the other illumination settings, the assignment is substantially closer to the ideal individual mirror column arrangement, as shown in FIG. 19. The correlation curve 19₁₅ shows the leaflet Y-hexapole illumination setting according to FIG. 18O, in the case of which illumination sections with in each case only a small extent are likewise present along the σ_{y}-pupil coordinate, and so the correlation depicted in FIG. 19 is likewise comparatively weak.

As a direct comparison, the correlation curve 19₁₆ provides the correlation for the leaflet X-hexapole illumination setting according to FIG. 18P. In that case there are two poles which extend along the σₓ-pupil coordinate, and these allow an individual mirror group assignment on the field facet mirror 6 with a less pronounced fragmentation, and so-as shown by a comparison of the correlation curves 19₁₅ and 19₁₆—a better assignment into the individual mirror columns than for the leaflet Y-hexapole illumination setting 18O overall arises for the leaflet X-hexapole illumination setting according to FIG. 18P.

The further correlation curves in FIG. 19 show gradual differences with respect to the distribution of the individual mirrors 21 that deviate from the ideal individual mirror column assignment. The best assignments are yielded by the y-dipole settings 18C (correlation curve 19₃), 18S (correlation curve 19₁₉) and 18Q (correlation curve 19₁₇).

For example, in the case of the illumination setting example according to FIG. 18C (leaflet Y-dipole) with the best correlation with regards to the individual mirror/field height assignment, more than 90% of the individual mirrors 19 deviate by less than 5 mm in the object field height dimensions from the ideal individual mirror column arrangement, and this corresponds to less than 5% of the original image field width.

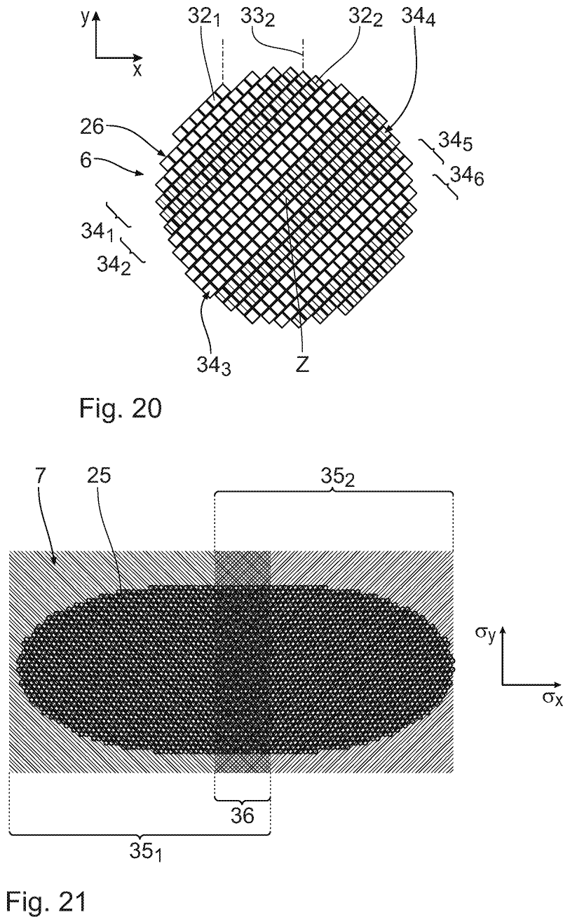

FIG. 20 shows the field facet mirror 6 in an illustration corresponding to that of FIG. 3. Moreover, FIG. 20 illustrates two pre-tilt types 32₁ (unfilled individual mirror groups 26) and 32₂ (hatched individual mirror groups 26) of the individual mirror groups 26. The two pre-tilt types 32₁ and 32₂ each include individual mirror units 26 that have a specific type-dependent pre-tilt angle, as specified by a carrier geometry of the field facet mirror 6, relative to a base tilt angle in a neutral position. For example, the first pre-tilt type 32₁ has a pre-tilt angle of 30 mrad about a pre-tilt axis parallel to the y-axis. This pre-tilt is the same for all individual mirror units 26 of the first pre-tilt type 32₁. The second pre-tilt type 32₂ has a correspondingly opposite pre-tilt through −30 mrad about a tilt axis 33₂ once again parallel to the y-axis. This pre-tilt angle is also the same in each case for the individual mirror units 26 of the second pre-tilt type 32₂.

The pre-tilt angle can be in a range of firstly between 10 mrad and 12 mrad and secondly between −100 mrad and −10 mrad.

An angle of incidence amplitude of the illumination light 3 at the individual mirrors 21 of the first facet mirror 6 can be ±4° or else ±3°.

The pre-tilt types 32ᵢ are also referred to as switching classes for the individual mirror units 26. Once assigned to the respective switching classes, individual mirrors 21 of the transfer facet mirror 6 and/or illumination specification facet mirror 7 can be used with different tilt angle ranges Δx, Δy and for example with a directionally dependent tilt angle range. The tilt angle ranges in the tilt angle dimensions Δx and Δy can have a ratio of between 10:1 and 1:10.

In the case of the occupancy according to FIG. 20, half of the individual mirror units 26 are part of the first pre-tilt type 32₁ and the other half are part of the second pre-tilt type 32₂. Thus, the number of individual mirror units 26 belonging to a respective pre-tilt type 32ᵢ is the same in each case. Depending on the pre-tilt type embodiment of the field facet mirror 6, these numbers might also differ but regularly do not differ from one another by more than 10% in each case.

In the case of the type assignment according to FIG. 20, the individual mirror units 26 of the pre-tilt types 32ᵢ are arranged in contiguous mirror surface sections 34₁ to 34₆ in each case. In this case, the pre-tilt type 32₁ occupies the mirror surface sections 34₁, 34₃ and 34₅. The pre-tilt type 32₂ occupies the mirror surface sections 34₂, 34₄ and 34₆. These three mirror surface sections 34₁, 34₃ and 34₅ on the one hand and 34₂, 34₄ and 34₆ on the other hand are separated from one another in each case by mirror surface sections of the respective other pre-tilt type.

The arrangement of the mirror surface pre-tilt type sections 34ᵢ on the field facet mirror 6 is two-fold point symmetric about a centre Z of the field facet mirror 6.

An extent of the respective mirror surface pre-tilt type sections 34ᵢ along the field height coordinate x of the first facet mirror 6 is greater than the original image width x_{SP} of the object field 8 on the field facet mirror 6. Thus, the x-extent of the respective mirror surface pre-tilt type section 34ᵢ is greater than the x-width of the individual mirror columns 27ᵢ.

With regards to the arrangement of the individual mirror units 26, the mirror surface pre-tilt type sections 34ᵢ are arranged line-by-line on the facet mirror 6.

FIG. 21 shows what regions of the second facet mirror 7 with the respective pre-tilt type 32ᵢ can be impinged upon by a respective illumination light component beam. The pre-tilt is such that individual mirrors 21 of the pre-tilt type 32₁ can impinge upon a target surface region 35₁ on the second facet mirror 7. An extent of the target surface region 35₁ along a pupil coordinate σₓ of the second facet mirror 7 that corresponds to the x-coordinate of the field facet mirror 6 is more than half the size of an overall extent of the second facet mirror 7 along this pupil coordinate σₓ. For example, this σₓ-extent ratio of the target surface region 35₁ to the overall extent is 60%.

A corresponding second target surface region 35₂ on the second facet mirror 7 can be impinged upon by the individual mirrors 21 of the second pre-tilt type 32₂.

Each of the second facets 25 of the second facet mirror 7 belongs to at least one of the two target surface regions 35₁ and/or 35₂. There is an overlap of the two target surface regions 35₁ and 35₂ in a σₓ-region 36. The second facets 25 arranged there thus belong to both target surface regions 35₁ and 35₂ and can be impinged upon by the illumination light 3 using individual mirrors 25 of both pre-tilt types 32₁ and 32₂.

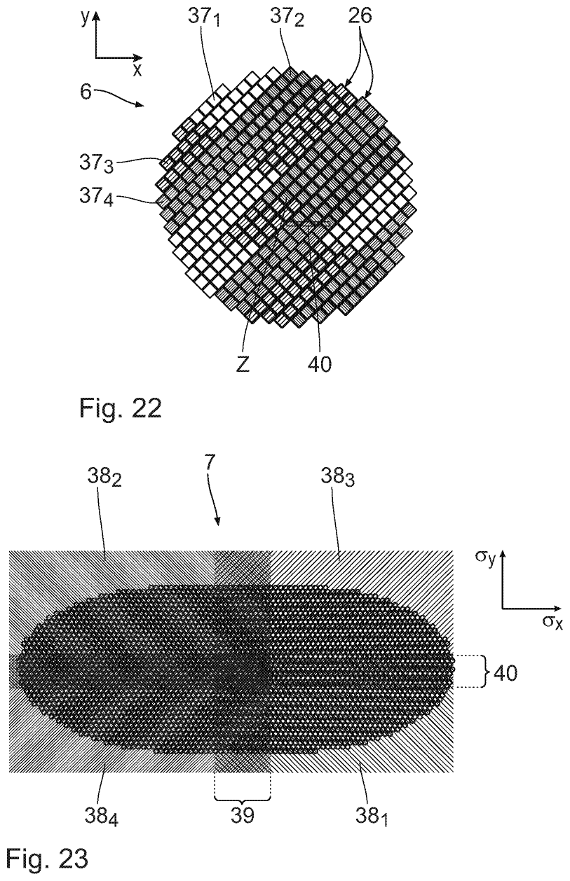

As an alternative or in addition to the various pre-tilt types 32ᵢ, the field facet mirror 6 might also comprise different coating types 37ᵢ, which is explained below on the basis of FIGS. 22 and 23.

FIG. 22 shows the field facet mirror 6, once again in an illustration corresponding to that of FIGS. 3 and 20. A subdivision of the field facet mirror 6 according to FIG. 22 into mirror surface pre-tilt type sections 34ᵢ corresponds to what was explained above on the basis of FIG. 20. Thus, once again, the field facet mirror 6 according to FIG. 22 has two pre-tilt types 32₁ and 32₂ in accordance with the explanation given in respect of FIG. 20.

In FIG. 22, different hatchings single out a total of four different coating types 37₁, 37₂, 37₃, 37₄ of the individual mirror units 26 of the field facet mirror 6.

The four coating types 37ᵢ are optimized for four different angle of incidence intervals of the illumination light 3 on the individual mirrors of the individual mirror units 36 of the coating type 37ᵢ.

The distribution of the pre-tilt types 32ᵢ on the one hand and of the coating types 37ᵢ on the other hand can be such that a plurality of coating types 37ᵢ are present within one mirror surface pre-tilt type section 34ᵢ. For example, the mirror surface pre-tilt type section 34₁ comprises the two coating types 37₁ and 37₃.

In an illustration corresponding to FIG. 21, FIG. 23 shows the target surface regions 38₁ to 38₄ on the second facet mirror 7, which are provided for guiding the illumination light component beams via one of the coating types 37ᵢ of the first facet mirror in each case. The target surface region 38₁ occupies the fourth quadrant on the second facet mirror 7. The target surface region 38₂ occupies the second quadrant on the second facet mirror 7. The target surface region 38₃ occupies the first quadrant on the second facet mirror 7. The target surface region 38₄ occupies the third quadrant on the second facet mirror 7.

Coordinates of extent σₓ, σ_{y} in an arrangement plane of the second facet mirror 7 are also referred to as pupil coordinates hereinafter, even though the second facet mirror 7 is regularly not arranged in the region of a pupil plane of the illumination optical unit 11. The arrangement coordinates σₓ, σ_{y} of the second facet mirror 7 correspond to the arrangement coordinates x, y of the first facet mirror 6.

Thus, a plurality of target surface regions 38ᵢ for guiding illumination light component beams over in each case one coating type 37ᵢ are present in each case along both pupil coordinates σₓ and σ_{y}, which are assigned firstly to the field height coordinate x and secondly to the object displacement coordinate y, on the second facet mirror 7.

Adjacent target surface regions 38ᵢ on the second facet mirror 7 overlap at least in part in overlap regions 39, 40. Thus, second facets 25 assigned to at least two different coating types 37ᵢ, 37ⱼ of the first facet mirror 6 are located in these overlap regions 39, 40. The two overlap regions 39 and 40 intersect in a rectangular double overlap region in the centre of the second facet mirror 7. The second facets 25 located there are accordingly located in all four target surface regions 38₁ to 38₄ and are accordingly assigned to all four coating types 37₁ to 37₄ of the first facet mirror 6.

This quadrant-by-quadrant split of the second facet mirror 7 into target surface regions for the coating types 37ᵢ takes account of both the folding of the illumination light in the illumination optical unit 11 and the extent aspect ratio of the second facet mirror 7, which deviates from 1 and is approximately two times larger in the σₓ-direction than in the σ_{y}-direction.

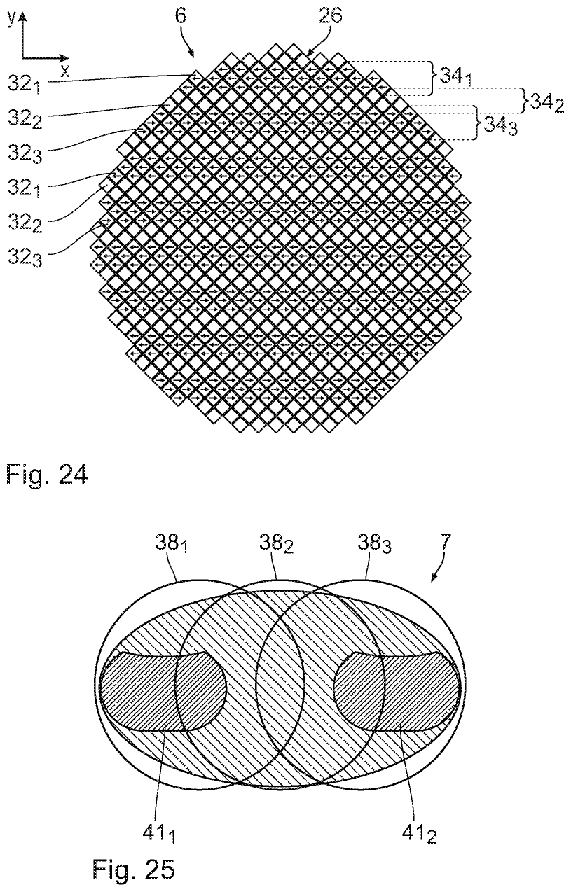

FIG. 24 shows a further variant of a subdivision of the first facet mirror 6 into pre-tilt types 32ᵢ. The field facet mirror 6 is shown in a plan view corresponding to that of FIG. 6. In FIG. 24, the assignment of the individual mirrors or individual mirror groups 26 to the respective pre-tilt types 32ᵢ is elucidated by different icons.

In the embodiment according to FIG. 24, the field facet mirror is subdivided into three pre-tilt types 32₁, 32₂, 32₃, which are tilted by different pre-tilt angles relative to the base tilt angle of the respective individual mirror unit 26 in each case.

In the embodiment according to FIG. 24, mirror surface pre-tilt type sections 34₁, 34₂ and 34₃, on which the respective pre-tilt types 32₁, 32₂ and 32₃ are arranged, run line-by-line along the x-coordinate.

Overall, there are twice as many individual mirrors of the central pre-tilt type 32₂ as individual mirrors of the other pre-tilt types 32₁ and 32₃. These two other pre-tilt types 32₁ and 32₃ are not directly adjacent to one another on the first facet mirror 6. Target surface regions 38ᵢ on the second facet mirror 7 (cf. FIG. 25), which are assigned to these pre-tilt types 32₁ and 32₃, have only a small overlap.

For example, the individual mirrors of the pre-tilt type 32₁ are tilted through −30 mrad, those of the pre-tilt type 32₂ through 0 mrad and those of the pre-tilt type 32₃ through +30 mrad.

Overall, the field facet mirror 6 according to FIG. 24 has eight mirror surface pre-tilt type sections 34₂ and in each case four mirror surface pre-tilt type sections 34₁ and 34₃.

FIG. 25 shows which target surface regions 38ᵢ on the second facet mirror 7 within an appropriately designed illumination optical unit 11 can be impinged upon by the individual mirrors 21 of the respective pre-tilt types 32ᵢ of the embodiment according to FIG. 24. The target surface region 38₂ represents the central region, with an elliptical or else circular boundary, of the second facet mirror 7. In FIG. 25, the two other target surface regions 38₁ and 38₃, once again with an elliptical or else circular embodiment, cover the left and right edge portion, respectively, of the second facet mirror 7. Adjacent target surface regions 38ᵢ, 38ᵢ₊₁ have a large overlap region, which is greater than 50% of the area of the respective target surface region 38ᵢ. Even the two extremal target surface regions 38₁ and 38₃ have a central overlap, which constitutes approximately 25% of the area of the respective target surface region 38ᵢ.

By way of example, those facet illumination regions 41₁, 41₂ of the second facet mirror 7 which are used to create an exemplary y-dipole illumination setting, which represents a variant of the y-dipole illumination setting explained above on the basis of FIG. 18, are singled out in FIG. 25 by way of hatching. These illumination regions 41₁, 41₂ are located completely within the edge-side target surface region 38₁ on the one hand and 38₃ on the other hand.

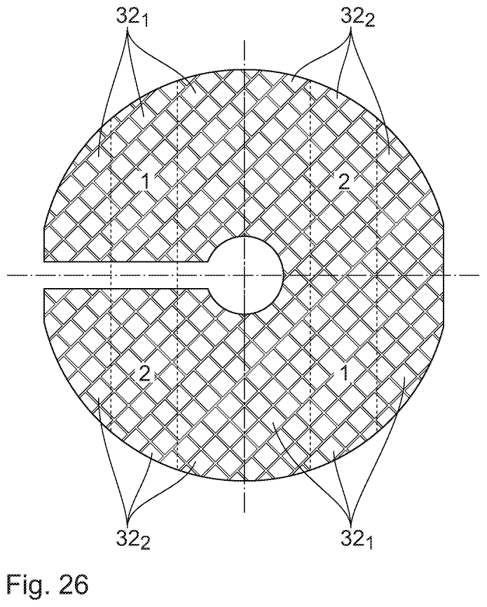

In an illustration of the field facet mirror 6 similar to FIG. 6, FIG. 26 shows a further subdivision of the individual mirrors 21 or individual mirror groups 26 into two different pre-tilt types 32₁ and 32₂. The second and the fourth quadrants (quadrants II/IV) on the field facet mirror 6 are occupied by individual mirrors of the pre-tilt type 32₁, and the first and third quadrants (quadrants I/III) are occupied by individual mirrors of the pre-tilt type 32₂.

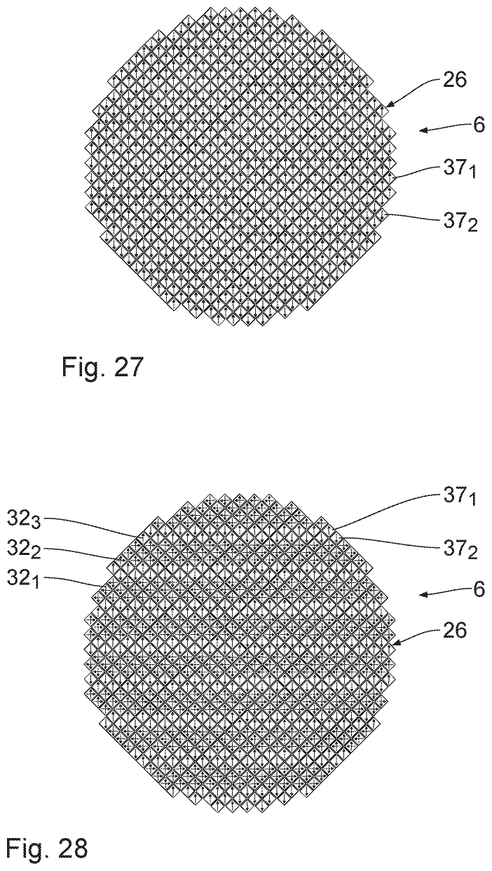

FIG. 27 shows a variant of a division of the first facet mirror 6 into coating types 37ᵢ. Differing coating types 37ᵢ are emphasized by different icons on the individual mirror units 26. The division according to FIG. 27 contains exactly two coating types: 37₁ (icon: arrow pointing upwards) and 37₂ (icon: arrow pointing downwards). The individual mirror units 26 of the coating type 37₁ are assigned to a first target surface region on the second facet mirror 7, and the individual mirror units 26 of the coating type 37₂ are assigned to a second target surface region on the second facet mirror 7.

For example, the coating types can be grouped line-by-line on the mirror surface sections.

FIG. 28 shows a combination of pre-tilt types 32ᵢ on the one hand and coating types 37ᵢ on the other hand on a further embodiment of the field facet mirror 6. The division here is into three pre-tilt types 32₁ (icon: arrow pointing to the left), 32₂ (icon: arrow pointing to the right) and 32₃ (icon: no horizontal arrow) and into two coating types 37₁ (icon: arrow pointing upwards) and 37₂ (icon: arrow pointing downwards). Accordingly, this gives rise to six different combinations of pre-tilt type and assigned coating type.

In the arrangement variants according to FIGS. 27 and 28, each mirror surface section with a specific pre-tilt type 32ᵢ or a specific coating type 37ᵢ comprises at least two lines of individual mirror units 26.

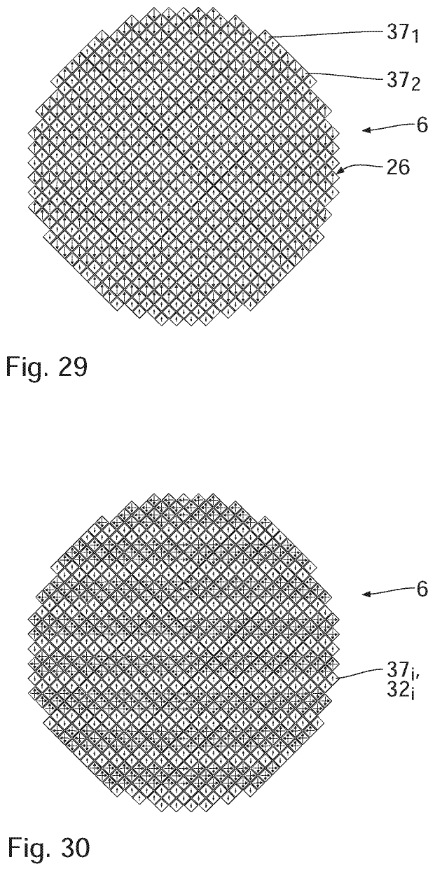

FIGS. 29 and 30, whose illustrations correspond to those of FIGS. 27 and 28, show further arrangement variants of pre-tilt types 32ᵢ and, respectively, combination variants of pre-tilt types 32ᵢ and coating types 37ᵢ.

FIGS. 29 and 30 illustrate soft transitions between the two extreme layer classes 37₁ (icon: longest arrow pointing upwards) and 37₂ (icon: longest arrow pointing downwards. In this case, shorter arrows indicate that individual mirror units of this coating type are designed to illuminate a relatively large target surface region on the second facet mirror 7, albeit sometimes with preference the target surface region of the coating type 37ᵢ associated with the arrow direction.

In the arrangements according to FIGS. 27 and 29, the mirror surface sections of the respective coating types 37ᵢ do not extend over an entire x-extent of the field facet mirror 6, but only over half an x-extent in each case.

The introduction of a plurality of pre-tilt types 32ᵢ or a plurality of coating types 37ᵢ allows a reduction in the angle of incidence travel on the respective individual mirror 21 of the first facet mirror 6, and a coating adapted thereto can be optimized better accordingly. An absolute angle of incidence on the respective individual mirror 21 can also be reduced.

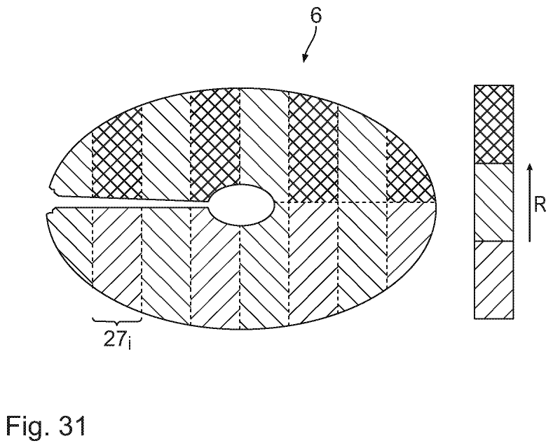

FIG. 31 illustrates a reflectivity-dependence over the individual mirrors 21 in one variant of the field facet mirror 6 with two coating types 37₁ and 37₂. A respective hatching according to the key depicted to the right in FIG. 31 in each case illustrates a mean reflectivity R of the respective surface section of the field facet mirror 6, which is impinged upon by the illumination light 3. Once again, the assignment of the individual mirrors to individual mirror columns 27ᵢ can be identified. Accordingly, the coating types 37ᵢ are sorted column-by-column. Reflectivities in the range between 60% and 65% and, for example, in the range between 63% and 64% can be achieved.

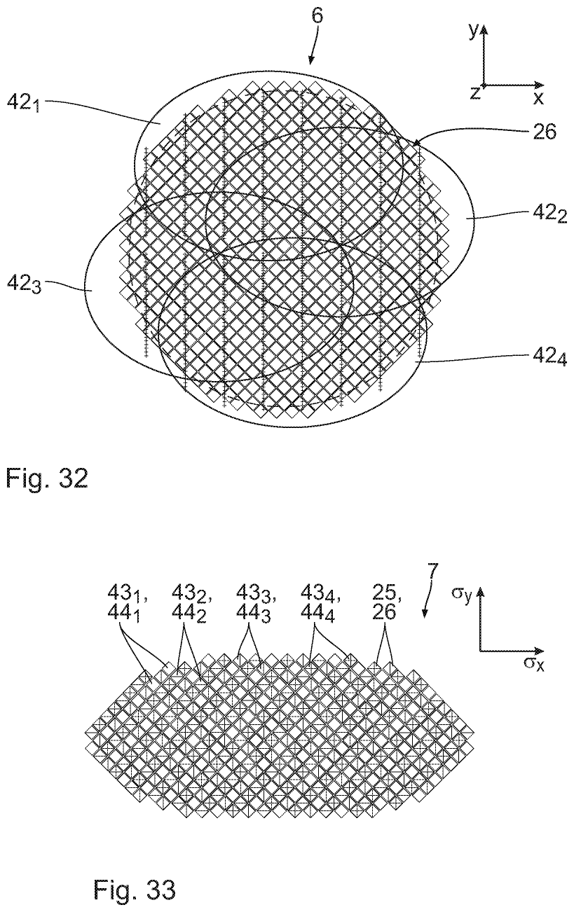

In an illustration similar to FIG. 25, FIG. 32 shows a subdivision of the first facet mirror 6 into initial surface regions 42ᵢ, which are assigned pre-tilt types 43ᵢ of the second facet mirror 7 and which are illustrated in FIG. 33 in turn by different hatching fills of the respective individual mirror units 26. In the division according to FIG. 32, all initial surface regions 42ᵢ are embodied as horizontal ellipses. All four initial surface regions 42₁ to 42₄ overlap in a central section of the field facet mirror 6.

In the embodiment of the second facet mirror 7 according to FIG. 33, each of the individual mirror units 26 represents a second facet 25. The design of the second facet mirror 7 according to FIG. 33 is an example of a design in which one and the same individual mirror type with individual mirror units 26 can be used both for the first facet mirror 6 and for the second facet mirror 7. Depending on the number of individual mirrors 21 per individual mirror unit 26, it is also possible to realize a plurality of second facets 25 for each individual mirror unit 26, for example four second facets 25 (2×2 sub-array on the individual mirror unit 26) or nine, sixteen or else twenty-five second facets 25 per individual mirror unit 26. Each of the second facets 25 in turn can be formed from one individual mirror 21, from four individual mirrors 21 (2×2 array of the individual mirrors 21), or from nine, sixteen, twenty-five or else thirty-six individual mirrors 21.

The individual mirror units 26 are arranged in chequerboard-like fashion or in a regular grid, wherein lines or columns of this arrangement are arranged at an angle of for example 45° with respect to the x-, y- or σₓ-, σ_{y}-coordinates. This angle can be in the range between 10° and 80°, for example in the range between 30° and 60°. For example, this angle can also be 37°.

The second facet mirror 7 according to FIG. 33 has a total of four pre-tilt types 43₁, 43₂, 43₃ and 43₄, which transfer illumination light 3 from the respective initial surface region 42₁, 42₂, 42₃, 42₄ to the object field 8 by way of a reflection at the respective second facet 25, which has been pre-tilted according to the respective pre-tilt type 43ᵢ.

With regards to the pre-tilt angles of the various pre-tilt types 43ᵢ, the explanations given above in respect of the pre-tilt angles in the pre-tilt types 32ᵢ of the first facet mirror 6 apply accordingly.

The pre-tilt types 43₁ to 43₄ alternate along a line of the second facet mirror 7, for example along the σₓ-coordinate. The same number of individual mirror units 26 of the second facet mirror 7 in each case belong to a respective one of the pre-tilt types 43ᵢ.

The initial surface regions 42ᵢ on the first facet mirror 6 have elliptical envelopes and are offset from one another both along the x-coordinate and along the y-coordinate. Adjacent initial surface regions 42ᵢ, 42ᵢ₊₁ overlap one another in overlap regions.

For example, adjacent individual mirror units 26 of the second facet mirror 7 belong to different pre-tilt types 43ᵢ, 43ⱼ.

The pre-tilt types 43ᵢ can regularly be arranged on the second facet mirror 7 in a manner alternating in chequerboard-like or regular grid-like fashion.

Adjacent second facets 25 belong to different pre-tilt types 43ᵢ and 43ⱼ.

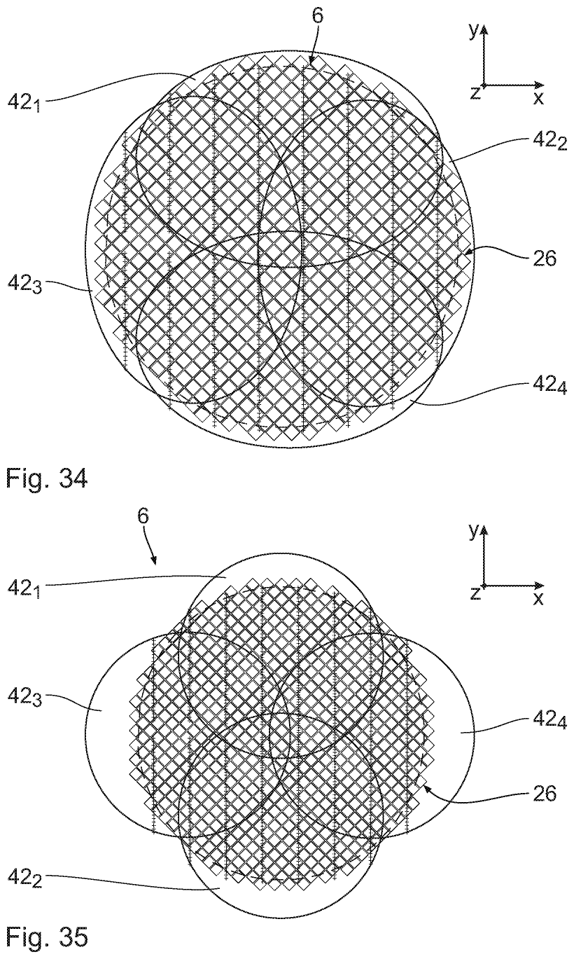

FIGS. 34 and 35 are used to explain further divisions of the first facet mirror 6 into the initial surface regions 42ᵢ, in accordance with the division according to FIG. 32.

The division according to FIG. 34 once again yields four initial surface regions 42₁, 42₂, 42₃ and 42₄ with elliptical boundaries.

Two of the initial surface regions, specifically the regions 42₁ and 42₂, are embodied as horizontal ellipses, and the two other initial surface regions 42₃ and 42₄ are embodied as horizontal ellipses.

All four initial surface regions 42₁ to 42₄ also overlap in a central section of the field facet mirror 6 in the embodiment according to FIG. 34.

The division according to FIG. 35 yields a total of four initial surface regions 42₁ to 42₄ with a circular boundary.

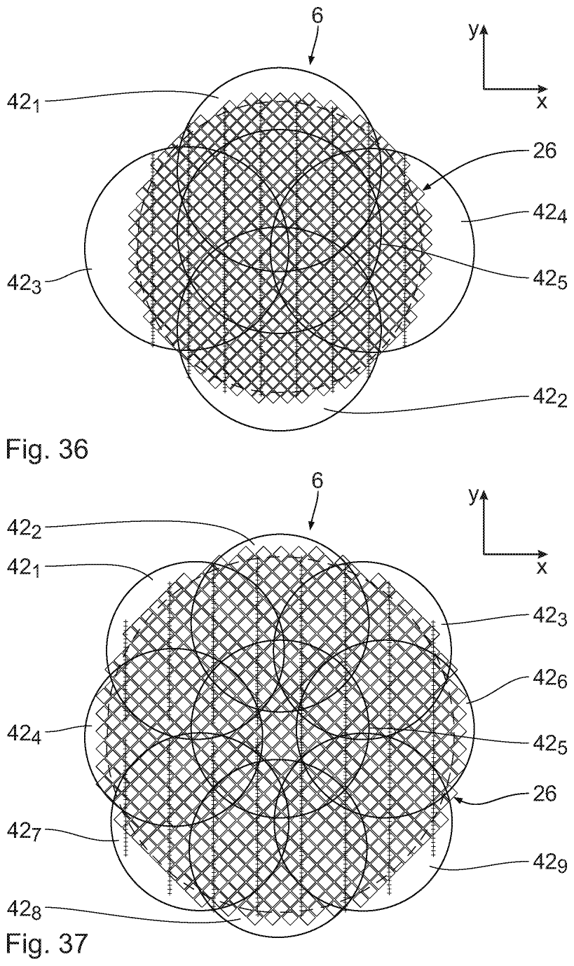

Further examples of a division of the field facet mirror 6 into initial surface regions 42ᵢ are shown in FIGS. 36 and 37.

In the design according to FIG. 36 there are a total of five initial surface regions 42₁ to 42₅. In this case, the initial surface regions 42₁ to 42₄ correspond to those according to FIG. 35. Moreover, provision is made of a fifth initial surface region 42₅, which covers an inner circular section of the field facet mirror 6.

FIG. 37 shows a division of the field facet mirror 6 into a total of nine initial surface regions 42₁ to 42₉. One of the initial surface regions, the initial surface region 42₅, represents a central section on the field facet mirror 6. The other eight initial surface regions 42₁ to 42₄ and 42₆ to 42₉ are arranged around this central initial surface region 42₅.

In the divisions of the field facet mirror 6 explained above, at least three of the initial surface regions 42ᵢ, 42ⱼ, 42ₖ overlap with one another in each case, to form a common section.

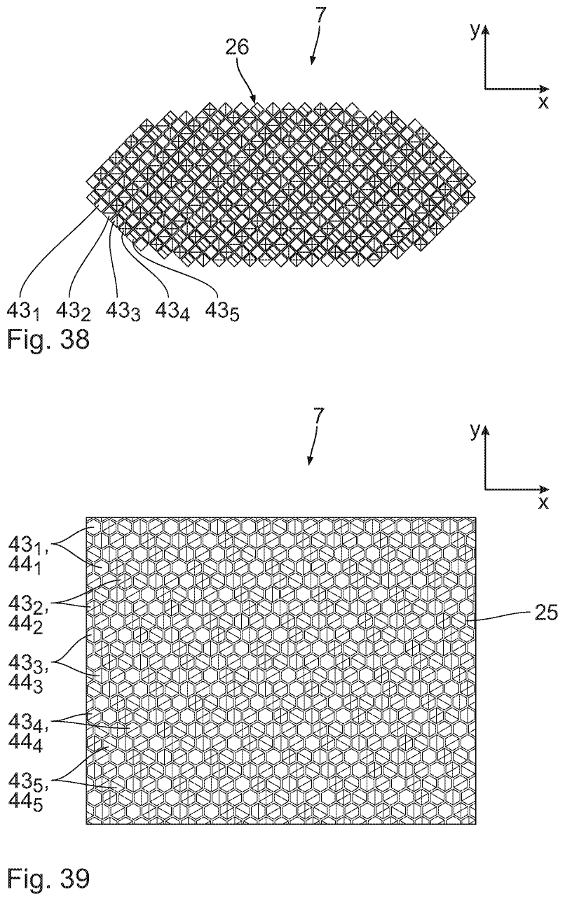

In an illustration similar to FIG. 33, FIG. 38 shows an occupancy of the second field facet mirror 7 with a total of five pre-tilt types 43₁ to 43₅, which are indicated by respective icons.

FIG. 39 shows an occupancy of a variant of the second facet mirror 7 with monolithic second facets 25 in the style of the embodiment of FIG. 5, wherein five different pre-tilt types 43₁ to 43₅ of these second facets 25 are present in the embodiment according to FIG. 39. Once again, adjacent field facets 25 belong to different pre-tilt types 43ᵢ, 43ⱼ.

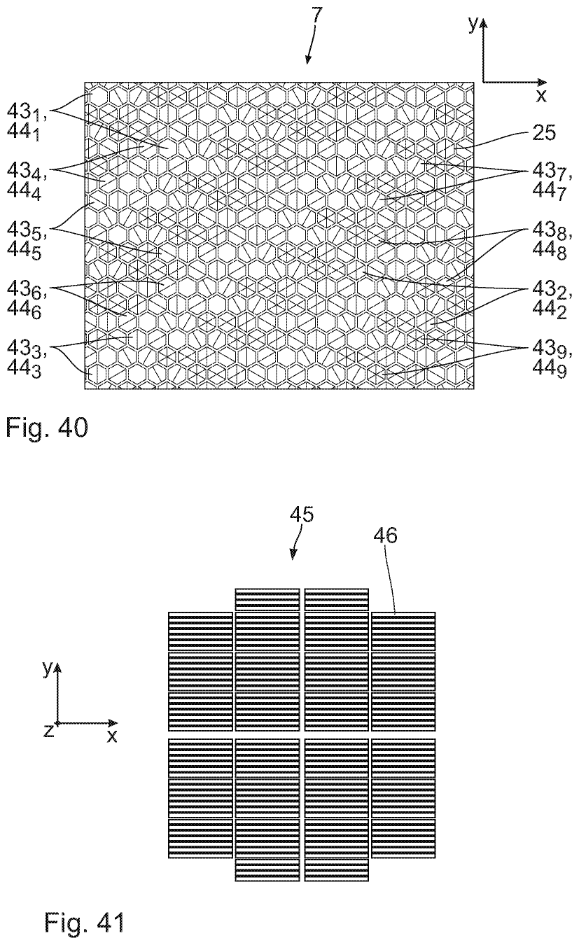

In an illustration similar to FIG. 39, FIG. 40 shows the design of the second field facet mirror 7 with a total of nine pre-tilt types 43₁ to 43₉.

In addition to a subdivision into various pre-tilt types 43ᵢ, the second facets 25 can also be subdivided into different coating types 44ᵢ in accordance with the statements already given above, firstly in relation to the pre-tilt types 43ᵢ of the second facet mirror 7 and secondly in relation to the coating types 37ᵢ of the first facet mirror 6. Each pre-tilt type 43ᵢ can be assigned a dedicated coating type 44ᵢ on the second facet mirror 7. Alternatively, one and the same pre-tilt type 43ᵢ can be assigned different coating types 44ᵢ. In yet a further alternative to that or in addition, it is possible to assign different pre-tilt types 43ᵢ to one and the same coating type 44ᵢ.

Once again, it is possible to realize a reduction of a maximum angle of incidence and a reduction of a maximum angle of incidence travel on the second facets 25, and this helps optimize a reflection yield of the second facet mirror 7, by way of the various pre-tilt types 43ᵢ and the various coating types 44ᵢ of the second facets 25 of the second facet mirror 7.

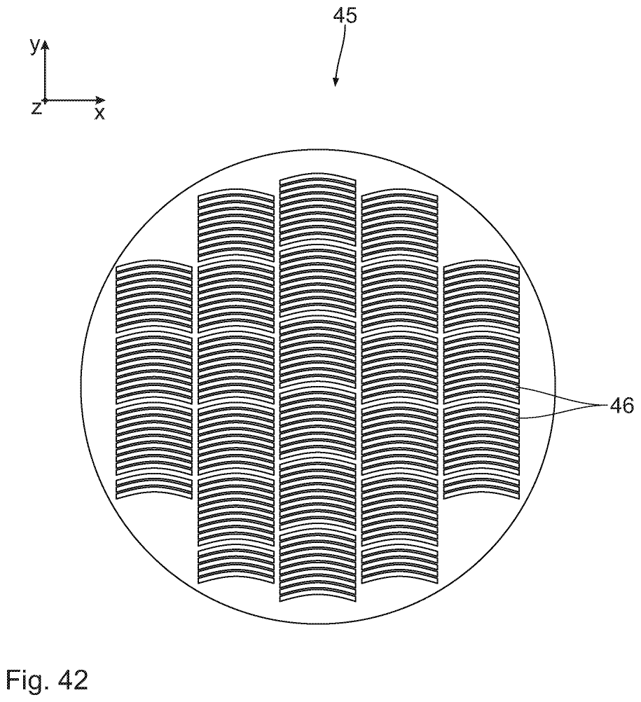

FIGS. 41 and 42 show variants of the first facet mirror 45, which can be used instead of the first facet mirror 6. Components and functions corresponding to those which have already been explained above, for example with reference to the first facet mirror 6, bear the same reference signs and will not be discussed in detail again.

Instead of individual mirror groups 30ᵢ, the first facet mirror 45 according to FIGS. 41 and 42 has monolithic first facets 46, which have a rectangular embodiment in the design according to FIG. 41 and an arcuate embodiment in the design according to FIG. 42. The first facets 46 are arranged column-by-column and in groups within the columns. With regards to details of this arrangement, reference is made to DE 10 2009 030 501 A1.

In order to produce a microstructured component, for example a highly integrated semiconductor component, for example a memory chip, with the aid of the projection exposure apparatus 1, firstly the reticle 12 and the wafer 19 are provided. Subsequently, a structure on the reticle 12 is illuminated by the illumination light 3 using the illumination optical unit 11 and is projected onto a light-sensitive layer on the wafer 19 using the projection optical unit of the projection exposure apparatus 1. By developing the light-sensitive layer, a microstructure is then produced on the wafer 19 and the microstructured or nanostructured component is produced therefrom.

The component produced can be a microchip, for example a memory chip.

1. A facet mirror for a projection lithography illumination optical unit configured to be used as a facet mirror such that individual mirror groups of the facet mirror, as first facets, are imageable at least into partial fields of an object field of the illumination optical unit with the aid of a transfer optical unit, an object being arrangeable in said object field and being displaceable in an object displacement direction through the object field during a projection exposure, the facet mirror comprising:
an array arrangement of individual mirror units, with each of the individual mirror units being a sub-array of individual mirrors, the array arrangement comprising first and second pre-tilt types of the individual mirror units,
wherein:
the first pre-tilt type comprises individual mirror units which, in a neutral position, have a first pre-tilt angle relative to a base tilt angle specified by a carrier geometry of the facet mirror;
the second pre-tilt type comprises individual mirror units which, in the neutral position, have a second pre-tilt angle relative to the base tilt angle;
the first and second pre-tilt angles differing from one another; and
each of the first and second pre-tilt angles are in the range between 10 mrad and 500 mrad.

2. The facet mirror of claim 1, wherein the individual mirror units of the first pre-tilt type are in groups of individual mirror units in at least one contiguous mirror surface pre-tilt type section of the facet mirror.

3. The facet mirror of claim 2, wherein there is a twofold or multiply rotationally symmetric arrangement of the mirror surface pre-tilt type sections, in which different ones of the pre-tilt types are arranged.

4. The facet mirror of claim 2, wherein there is an extent of the respective mirror surface pre-tilt type section along a field height coordinate of the facet mirror which is imageable via the illumination optical unit into a field height coordinate perpendicular to the object displacement coordinate of the object field, and the extent is greater than an original image width of the object field on the facet mirror along the field height coordinate.

5. The facet mirror of claim 2, wherein the mirror surface pre-tilt type sections are line-by-line on the facet mirror.

6. An illumination optical unit, comprising:
a first facet mirror;
a second facet mirror; and
a transfer optical unit,
wherein:
the illumination optical unit is configured so that individual mirror groups of the first facet mirror, as first facets, are imageable at least into partial fields of an object field of the illumination optical unit via the transfer optical unit, an object being arrangeable in the object field and being displaceable in an object displacement direction through the object field during a projection exposure;
the first facet mirror comprises:
a regular array arrangement of individual mirror units, each individual mirror unit comprising a sub-array of individual mirrors; and
first and second coating types of the individual mirror units
the first coating type comprises individual mirror units which, in a neutral position, are optimized for a first angle of incidence of illumination light on the individual mirror units of this coating type;
the second coating type comprises individual mirror units which, in the neutral position, are optimized for a second angle of incidence of the illumination light on the individual mirror units of this coating type;
the angles of incidence of the first and second coating types differ from one another;
the second facet mirror is configured to reflectively guide the illumination light reflected by the first facet mirror to the object field;
the second facet mirror comprises second facets configured to image groups of individual mirrors of the first facet mirror, as first facets, at least into partial fields of the object field via illumination light component beams;
at least two target surface regions are present on the second facet mirror along a field height arrangement coordinate of the second facet mirror of the illumination optical unit;
the field height arrangement coordinate corresponds to a field height coordinate of the first facet mirror which is imageable via the illumination optical unit into a field height coordinate perpendicular to the object displacement direction coordinate of the object field; and
the target surface regions are configured to guide illumination light via a pre-tilt type in each case and/or via a coating type of the first facet mirror in each case.

7. The illumination optical unit of claim 6, wherein the individual mirror units of at least one of the coating types of the first facet mirror are in groups of individual mirror units in at least one contiguous mirror surface coating type section of the facet mirror.

8. The illumination optical unit of claim 6, wherein:
at least two target surface regions are present on the second facet mirror along an object displacement arrangement coordinate of the second facet mirror;
the object displacement arrangement coordinate corresponds to an object displacement coordinate of the first facet mirror which is imageable via the illumination optical unit into the object displacement direction coordinate of the object field;
each target surface region configured to guide illumination light via a pre-tilt type in each case and/or via a coating type of the first facet mirror in each case.

9. The illumination optical unit of claim 6, wherein the target surface regions at least partially overlap on the second facet mirror.

10. An illumination optical unit, comprising:
a first facet mirror comprising first facets configured to reflectively guide component beams of illumination light;
a transfer optical unit; and
a second facet mirror configured to reflectively guide the illumination light reflected by the first facet mirror to an object field of the illumination optical unit,
wherein:
the illumination optical unit is configured so the first facets of the first facet mirror are imageable at least into partial fields of the object field of the illumination optical unit via the transfer optical unit, which includes second facets of the second facet mirror;
an object is arrangeable in the object field and is displaceable in an object displacement direction through the object field (8) during a projection exposure;
the second facet mirror comprises:
first and second pre-tilt types of the second facets, the first pre-tilt type comprising second facets which, in a neutral position, have a first pre-tilt angle relative to a base tilt angle specified by a carrier geometry of the facet mirror, the second pre-tilt type comprising second facets which, in the neutral position, have a second pre-tilt angle relative to the base tilt angle, the first and second pre-tilt angles differing from one another; and/or
first and second coating types of the second facets, the first coating type comprising second facets and/or individual mirror units optimized for a first interval of angles of incidence of illumination light on the second facets and/or the individual mirror units of the first coating type, the second coating type comprising second facets and/or individual mirror units optimized for a second interval of angles of incidence of the illumination light on the second facets and/or the individual mirror units of the second coating type, the first and second interval angles of incidence differing from one another;
wherein the second facets of the second facet mirror are configured to image first facets at least into partial fields of the object field via illumination light component beams;
at least two initial surface regions are present on the first facet mirror along a field height coordinate of the first facet mirror of the illumination optical unit;
the field height coordinate is imageable via the illumination optical unit into a field height coordinate perpendicular to the object displacement coordinate of the object field; and
each of the initial surface regions are configured to guide illumination light component beams via a pre-tilt type in each case and/or via a coating type of the second facet mirror in each case.

11. The illumination optical unit of claim 10, wherein there is an array arrangement of individual mirror units of the second facet mirror, each of the second facets comprises a sub-array of individual mirrors of the respective individual mirror unit, and all individual mirrors of an individual mirror unit belong to exactly one pre-tilt type.

12. The illumination optical unit of claim 10, wherein adjacent individual mirror units of the second facet mirror belong to different pre-tilt types.

13. The illumination optical unit of claim 10, wherein each of the second facets is a monolithic facet.

14. The illumination optical unit of claim 13, wherein adjacent second facets belong to different pre-tilt types.

15. The illumination optical unit of claim 10, wherein at least two initial surface regions are present on the first facet mirror along an object displacement coordinate of the first facet mirror, the object displacement coordinate is imageable via the illumination optical unit into the object displacement direction coordinate of the object field, and each of the initial surface regions is configured to guide illumination light component beams via a pre-tilt type in each case and/or via a coating type in each case.

16. The illumination optical unit of claim 10, wherein the initial surface regions are arranged with at least partial overlap on the first facet mirror.

17. An illumination system, comprising:
an illumination optical unit according to claim 6; and
a light source.

18. An optical system, comprising:
a light source;
an illumination optical unit according to claim 6; and
a projection optical unit configured to image the object field into an image field.

19. A projection exposure apparatus, comprising:
a light source;
an illumination optical unit according to claim 6; and
a projection optical unit configured to image the object field into an image field.

20. A method of producing a microstructured component using a projection exposure apparatus comprising an illumination optical unit and a projection optical unit, the method comprising:
using the illumination optical unit to illuminate a reticle in an object field of the projection optical unit;
using the projection optical unit to image the reticle into an image field of the projection optical unit onto a light sensitive-material in an image plane of the projection optical unit; and
developing the light-sensitive layer,
wherein the illumination optical unit is an illumination optical unit according to claim 6.

21.-24. (canceled)
